(19) United States
(12) Patent Application Publication
(10) Pub. No.: US 2025/0079382 A1
(43) Pub. Date: Mar. 6, 2025

(54) SEMICONDUCTOR PACKAGE AND METHOD OF MANUFACTURING SEMICONDUCTOR PACKAGE

(71) Applicant: Samsung Electronics Co., Ltd., Suwon-si (KR)

(72) Inventors: Jaeean Lee, Suwon-si (KR); Dongwon Kang, Suwon-si (KR); Dahee Kim, Suwon-si (KR); Changyeon Song, Suwon-si (KR); Sunguk Lee, Suwon-si (KR)

(21) Appl. No.: 18/807,488

(22) Filed: Aug. 16, 2024

(30) Foreign Application Priority Data
Aug. 29, 2023 (KR) 10-2023-0113970

(51) Int. Cl. H01L 23/00; H01L 23/31; H01L 23/538

(52) U.S. Cl. CPC H01L 24/20; H01L 24/19; H01L 23/3107; H01L 23/5385; H01L 2224/19; H01L 2224/2101; H01L 2224/221

(57) ABSTRACT

Provided is a semiconductor package including a lower package substrate including lower insulating layers, a first semiconductor device mounted on the lower package substrate, a core layer on the lower package substrate to be laterally spaced apart from the first semiconductor device, an encapsulation material surrounding the first semiconductor device and covering an upper portion of the core layer, an upper package substrate disposed on the encapsulation material, the upper package substrate including a first upper redistribution layer and a second upper redistribution layer; wherein a first line width and a first line spacing of a first fine pattern of the first upper redistribution pattern are greater than or equal to a corresponding second line width and a corresponding second line spacing of a second fine pattern of the second upper redistribution pattern, respectively.

### CROSS-REFERENCE TO RELATED APPLICATION

This application is based on and claims priority under 35 U.S.C. § 119 to Korean Patent Application No. 10-2023-0113970, filed on Aug. 29, 2023, in the Korean Intellectual Property Office, the disclosure of which is incorporated by reference herein in its entirety.

### BACKGROUND

The inventive concept relates to a semiconductor package and a method of manufacturing the semiconductor package, and more particularly, to a panel-level semiconductor package and a method of manufacturing the semiconductor package.

In the electronic product market, the demand for portable devices has rapidly increased. Miniaturization and lightening of electronic components mounted on these electronic products continues to be desirable. For miniaturization and lightening of electronic components, a semiconductor package mounted on the electronic components is required to process high capacity data while the volume of the semiconductor package is gradually reduced. Recently, a panel-level package (PLP) technology of performing a semiconductor package process at a panel level and dividing a panel-level semiconductor structure on which the semiconductor package process is performed into separate packages has been proposed.

### SUMMARY

The inventive concept provides a semiconductor package in which a line width of a fine pattern included in a redistribution pattern of an upper package substrate is further refined.

It will be appreciated by persons skilled in the art that the objects that could be achieved with the inventive concept are not limited to what has been particularly described hereinabove and the above and other objects that the inventive concept could achieve will be more clearly understood from the following detailed description.

According to an aspect of the inventive concept, there is provided a semiconductor package comprising: a lower package substrate including lower insulating layers; a first semiconductor device mounted on the lower package substrate; a core layer on the lower package substrate, the core layer being laterally spaced apart from the first semiconductor device and including: a core substrate, core vias passing through the core substrate, and core patterns connecting the core vias to each other; an encapsulation material surrounding the first semiconductor device and covering an upper portion of the core layer; and an upper package substrate disposed on the encapsulation material, the upper package substrate including a first upper redistribution layer and a second upper redistribution layer, wherein the first upper redistribution layer includes a first upper insulating layer and a first upper redistribution pattern on the first upper insulating layer, the second upper redistribution layer includes a second upper insulating layer on the first upper insulating layer and a second upper redistribution pattern on the second upper insulating layer, a first line width of a first fine pattern of the first upper redistribution pattern is greater than or equal to a corresponding second line width of a second fine pattern of the second upper redistribution pattern, and a first line spacing of the first fine pattern is greater than or equal to a corresponding second line spacing of the second fine pattern.

According to another aspect of the inventive concept, there is provided a method of manufacturing a semiconductor package, the method including forming a first process structure including: a lower package substrate, a first semiconductor device mounted on the lower package substrate, a core layer mounted on the lower package substrate, and the core layer being laterally spaced apart from the first semiconductor device, and an encapsulation material surrounding the first semiconductor device on the lower package substrate, the encapsulation material being on the core layer; forming a first upper redistribution layer, the first upper redistribution layer including: a first upper insulating layer on the encapsulation material of the first process structure and a first upper redistribution pattern on the first upper insulating layer; and forming a second upper redistribution layer, the second upper redistribution layer including: a second upper insulating layer on the first upper redistribution layer and a second upper redistribution pattern on the second upper insulating layer, wherein the forming of the first upper redistribution layer includes: forming the first upper insulating layer on the encapsulation material; forming, by recessing a portion of the encapsulation material, a plurality of first upper via holes which pass through the first upper insulating layer and through which a portion of the core layer is exposed; forming a first seed layer on the first upper insulating layer having the plurality of first upper via holes; and forming first upper via patterns in the plurality of first upper via holes, the first upper via patterns being electrically connected to the core layer, and forming first upper line patterns on the first upper via patterns, wherein the forming of the second upper redistribution layer includes: forming a second upper insulating layer on the first upper redistribution layer; forming a plurality of second upper via holes through the second upper insulating layer; forming a second seed layer on the second upper insulating layer having the plurality of second upper via holes; forming a resist layer on the second upper insulating layer on which the second seed layer is formed; and forming second upper via patterns on the plurality of second upper via holes and forming second upper line patterns on the second upper via patterns, wherein a material of the first upper insulating layer and a material of the second upper insulating layer are different from each other, the first upper redistribution pattern and the second upper redistribution pattern are formed such that a first line width of a first fine pattern of the first upper redistribution pattern is greater than or equal to a corresponding second line width of a second fine pattern of the second upper redistribution pattern, the first upper redistribution pattern and the second upper redistribution pattern are formed such that a first line spacing of the first fine pattern is greater than or equal to a corresponding second line spacing of the second fine pattern, and the first seed layer is formed via electroless plating and the second seed layer is formed using a sputter process.

According to another aspect of the inventive concept, there is provided a method of manufacturing a semiconductor package, the method including forming a first process structure including: a lower package substrate, a first semiconductor device mounted on the lower package substrate, a core layer mounted on the lower package substrate, the core layer being laterally spaced apart from the first semiconductor device, and an encapsulation material surrounding the first semiconductor device on the lower package substrate, the encapsulation material being on the core layer; forming a first upper redistribution layer, the first upper redistribution layer including: a first upper insulating layer on the encapsulation material of the first process structure and a first upper redistribution pattern on the first upper insulating layer; and forming a second upper redistribution layer, the second upper redistribution layer including: a second upper insulating layer on the first upper redistribution layer and a second upper redistribution pattern on the second upper insulating layer, wherein the forming of the first upper redistribution layer includes: forming the first upper insulating layer on the encapsulation material; forming, by recessing a portion of the encapsulation material, a plurality of first upper via holes which pass through the first upper insulating layer and through which a portion of the core layer is exposed; forming a first seed layer on the first upper insulating layer having the plurality of first upper via holes; and forming first upper via patterns in the plurality of first upper via holes, the first upper via patterns being electrically connected to the core layer, and forming first upper line patterns on the first upper via patterns, the forming of the second upper redistribution layer includes: forming a second upper insulating layer on the first upper redistribution layer; forming a plurality of second upper via holes through the second upper insulating layer; forming a second seed layer on the second upper insulating layer having the plurality of second upper via holes; forming a resist layer on the second upper insulating layer on which the second seed layer is formed; and forming second upper via patterns on the plurality of second upper via holes and forming second upper line patterns on the second upper via patterns, wherein a material of the first upper insulating layer and a material of the second upper insulating layer are identical to each other, and the first seed layer and the second seed layer are each formed using a sputter process.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIG. 2 is a diagram showing a cross section of a semiconductor package according to an embodiment;

FIG. 3 is a cross-sectional view of a semiconductor package according to an embodiment;

FIG. 4 is a cross-sectional view of a semiconductor package according to an embodiment;

FIG. 5 is a flowchart for explaining a semiconductor package manufacturing method according to an embodiment;

FIG. 6 is a flowchart for explaining in more detail a semiconductor package manufacturing method according to an embodiment;

FIGS. 7A to 7F are cross-sectional views for explaining the semiconductor package manufacturing method according to an embodiment;

FIGS. 8A to 8J are cross-sectional views for explaining the semiconductor package manufacturing method according to an embodiment;

FIG. 9 is a flowchart for explaining the semiconductor package manufacturing method according to an embodiment; and

FIGS. 10A to 10J are cross-sectional views for explaining a semiconductor package manufacturing method according to an embodiment.

### DETAILED DESCRIPTION OF THE EMBODIMENTS

Hereinafter, embodiments will be described in detail with reference to the attached drawings. The same reference numerals are used for the same components in the drawings, and repetitions thereof are omitted.

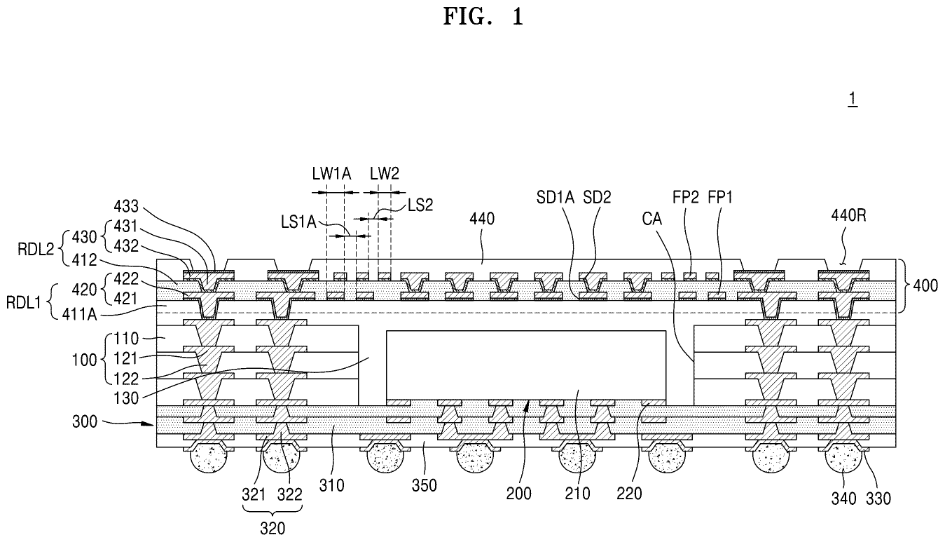

FIG. 1 is a cross-sectional view of a semiconductor package 1 according to an embodiment.

Referring to FIG. 1, the semiconductor package 1 includes a semiconductor chip 200, a lower package substrate 300 disposed below the semiconductor chip 200, a core layer 100 having a through hole CA to mount the semiconductor chip 200 therein, an encapsulation material 130 surrounding a side surface and upper surface of the semiconductor chip 200 and an upper surface and a partial side surface of the core layer 100, and an upper package substrate 400 disposed on the encapsulation material 130. The semiconductor package 1 may be a fan-out type semiconductor package in which connection pads 220 of the semiconductor chip 200 are externally redistributed. In the specification, the semiconductor chip 200 may be referred to as a first semiconductor device.

The core layer 100 may include the through hole CA passing through upper and lower surfaces thereof to mount the semiconductor chip 200 therein. As shown in FIG. 1, the through hole CA may be formed at the center of the core layer 100, but the number and arrangement of the through holes CA are not limited to the diagram. In some embodiments, the through hole CA may have a cavity shape rather than completely passing through the lower surface of the core layer 100. For example, the through hole CA may not pass completely through the lower surface of the core layer 100, and a portion of the core layer 100 may remain underneath the through hole CA.

The core layer 100 may include a core insulating layer 110, core wiring layers 121, and core vias 122. The core wiring layers 121 and the core vias 122 may be arranged to electrically connect the upper and lower surfaces of the core layer 100 to each other. The core wiring layer 121 may be disposed inside the core insulating layer 110 but is not limited thereto. The core wiring layers 121 exposed through the lower surface of the core layer 100 among all the core wiring layers 121 may be embedded and disposed into the core insulating layer 110, which may be a structure based on a manufacturing process. The core insulating layer 110 may be referred to as a base substrate.

The core insulating layer 110 may be formed of or include an insulating material, for example, a thermosetting resin such as an epoxy resin or a thermoplastic resin such as a polyimide, and may further include an inorganic filler. Alternatively, the core insulating layer 110 may include a resin impregnated into a core material such as glass fiber, glass cloth, and glass fabric, for example, a prepreg, Ajinomoto build-up film (ABF), FR-4, or bismaleimide triazine (BT) in addition to an inorganic filler. The core insulating layer 110 may be a multilayer substrate including a plurality of layers.

The semiconductor chip 200 may be mounted in the through hole CA of the core layer 100 and may be spaced apart from an inner wall of the through hole CA. The first semiconductor chip 200 may be configured in a single or plural number. The semiconductor chip 200 may include a semiconductor substrate 210 having an active surface and an inactive surface opposite to each other, and connection pads 220 disposed on the active surface of the semiconductor chip 200. For example, the semiconductor chip 200 may have a vertical direction thickness of about 150 μm or more.

The semiconductor chip 200 may have a face down arrangement in which the active surface of the semiconductor substrate 210 faces the lower package substrate 300 and may be mounted on an upper surface of the lower package substrate 300. In this case, the inactive surface of the semiconductor chip 200 may be referred to as an upper surface of the semiconductor chip 200, and a surface of the semiconductor substate 210, which is an opposite surface to the inactive surface of the semiconductor chip 200, may be referred to as a lower surface of the semiconductor chip 200.

The semiconductor substrate 210 may be formed of or include, for example, semiconductor materials such as silicon (Si) or germanium (Ge). Alternatively, the semiconductor substrate 210 may include a compound semiconductor material such as silicon carbide (SiC), gallium arsenide (GaAs), indium arsenide (InAs), and indium phosphide (InP). The semiconductor substrate 210 may include a well doped with impurities as a conductive area. The semiconductor substrate 210 may have a variety of device separation structures, such as a shallow trench isolation (STI) structure.

A semiconductor device including a plurality of individual devices of various types may be formed on the active surface of the semiconductor substrate 210. The plurality of individual devices may be electrically connected to the conductive area of the semiconductor substrate 210. The semiconductor device may further include conductive wiring or conductive plugs that electrically connect the plurality of individual devices to the conductive area of the semiconductor substrate 210. The plurality of individual devices may be electrically separated from other individual devices that neighbor each other by an insulating film.

In some embodiments, the semiconductor chip 200 may include a logic device. For example, the semiconductor chip 200 may be a central processing device chip, a graphics processing device chip, or an application processor (AP). In other embodiments, when the semiconductor package 1 includes the plurality of semiconductor chips 200, one of the plurality of semiconductor chips 200 may be a central processing device chip, a graphics processing device chip, or an AP chip, and another one may be a memory semiconductor chip including a memory device.

For example, the memory device may be a non-volatile memory device such as flash memory, a phase-change random access memory (PRAM), a magnetoresistive random access memory (MRAM), a ferroelectric random access memory (FeRAM) or a resistive random access memory (RRAM). In some embodiments, the memory device may be a volatile memory device such as a dynamic random access memory (DRAM) or a static random access memory (SRAM).

The semiconductor chip 200 may include the connection pads 220 disposed on the lower surface of the semiconductor chip 200. The connection pads 220 may be disposed to electrically connect the semiconductor chip 200 to other components. In some embodiments, a redistribution layer, a bump, or the like, which is connected to the connection pads 220, may be further disposed on the lower surface of the semiconductor chip 200. The connection pads 220 may be formed of or include a conductive material such as aluminum (Al). The semiconductor chip 200 may be electrically connected to a lower redistribution pattern 320 of the lower package substrate 300 through the connection pads 220.

On the lower package substrate 300, the connection pads 220 may be redistributed in a region outside the semiconductor chip 200 below the semiconductor chip 200. The lower package substrate 300 may include a plurality of lower insulating layers 310 and a lower redistribution pattern 320 including lower via patterns 321 and lower line patterns 322. The number and arrangement of the lower insulating layer 310, the lower via patterns 321, and the lower line patterns 322, which constitute the lower package substrate 300, are not limited to the diagrams, and may be changed in various ways in some embodiments.

The lower insulating layer 310 may be formed of or include an insulating material, such as a photo imageable dielectric (PID) resin. In this case, the lower insulating layers 310 may further include an inorganic filler. The lower insulating layers 310 may include the same materials or different materials. The lower redistribution pattern 320 including the lower via patterns 321 and the lower line patterns 322 may perform a function of redistribution the connection pads 220.

The lower line patterns 322 may be disposed on at least one of the upper and lower surfaces of the lower insulating layers 310. The lower via patterns 321 may be connected to portions of the lower line patterns 322 through the lower insulating layer 310.

The lower via patterns 321 may be completely filled with a conductive material, or may have a shape in which the conductive material is formed along a wall of the via. The lower redistribution pattern 320 may be formed of or include a conductive material, for example, copper (Cu), aluminum (Al), silver (Ag), tin (Sn), gold (Au), nickel (Ni), lead (Pb), titanium (Ti), or an alloy thereof.

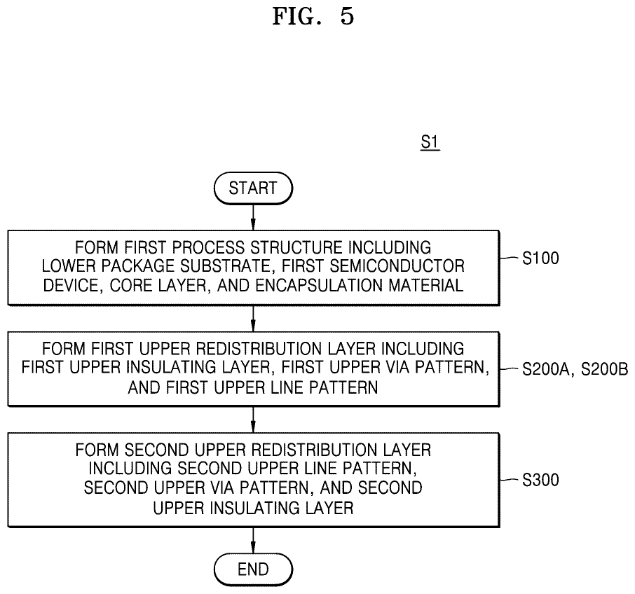

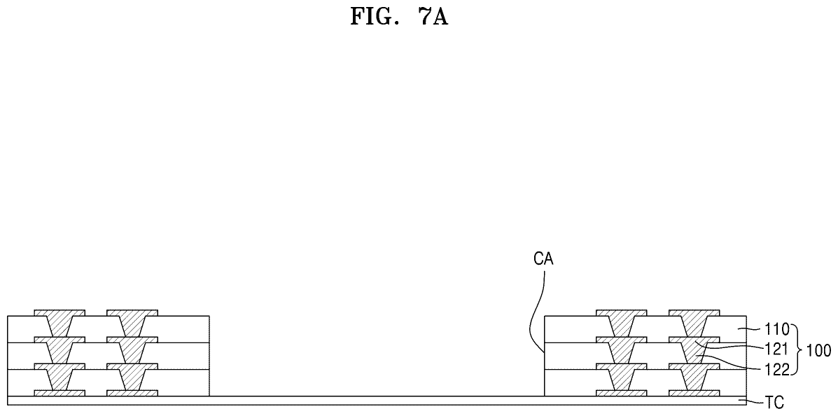

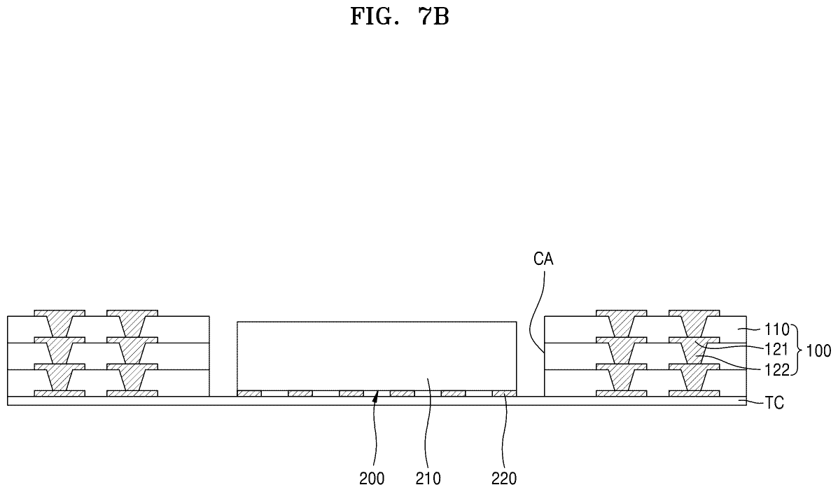

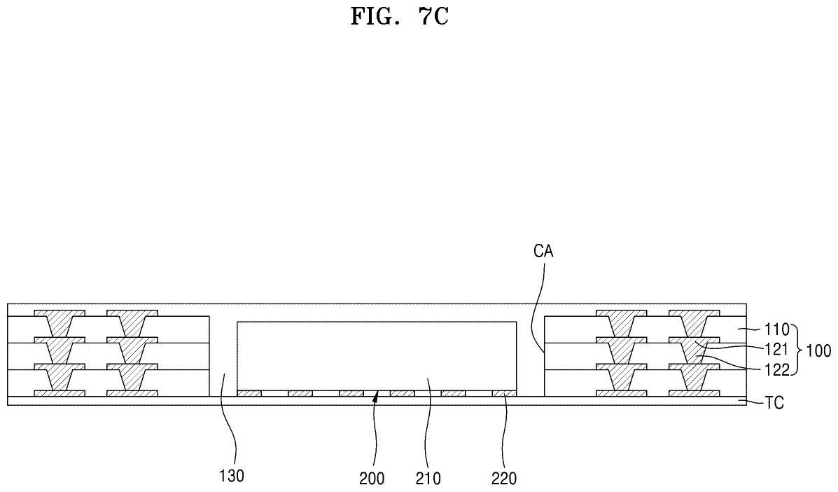

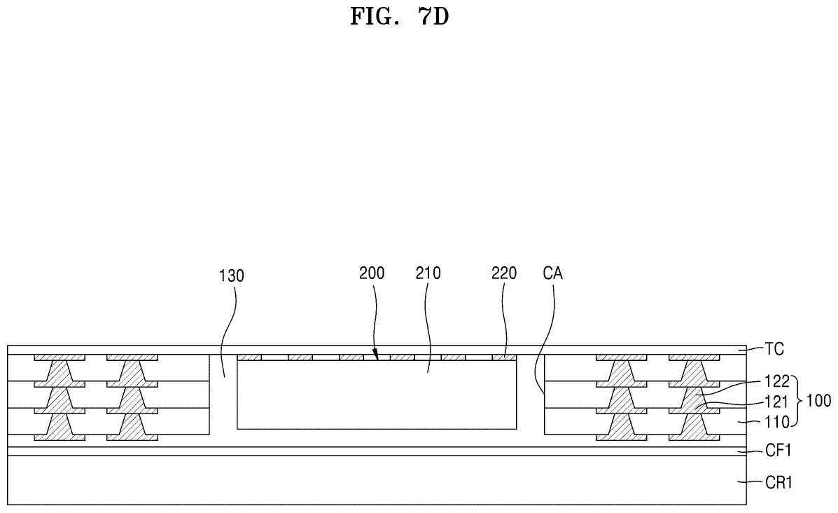

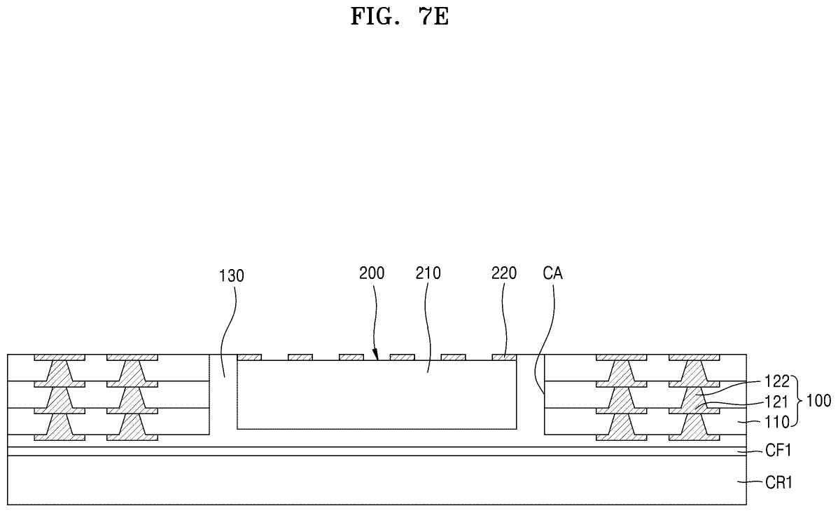

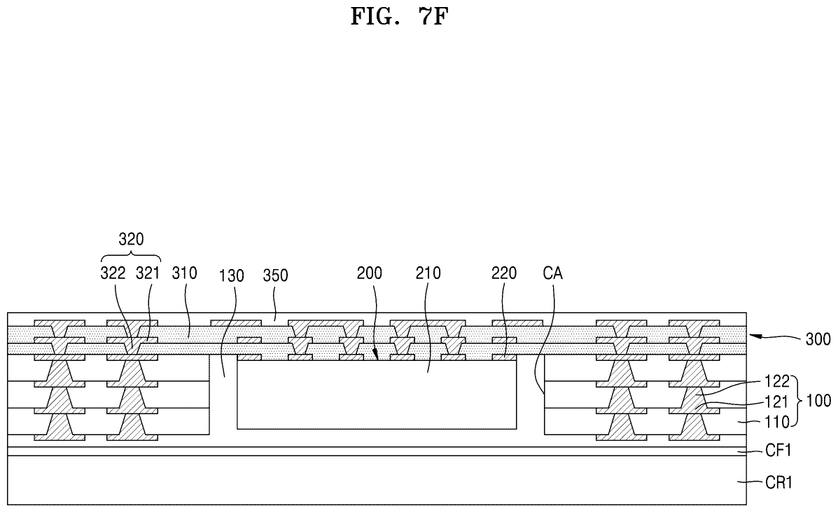

The lower surface of the semiconductor chip 200 may be in contact with the uppermost lower insulating layer 310 among all the lower insulating layers 310. It will be understood that when an element is referred to as “contacting” or “in contact with” another element (or using any form of the word “contact”), there are no intervening elements present at the point of contact. In a semiconductor package manufacturing method S1, which is a manufacturing process of the semiconductor package 1 according to an embodiment described below (see, e.g., FIG. 5), the lower package substrate 300 may be formed on the lower surface of the semiconductor chip 200 by a chip-first process. As described below with reference to FIG. 7F, according to the order in which the lower package substrate 300 is formed, in the semiconductor package 1 according to an embodiment, the lower via patterns 321 may have a tapered shape, a horizontal width of which increases away from the semiconductor chip 200.

A lower passivation layer 350 may be disposed on the lower surface of the lower package substrate 300 and may protect the lower package substrate 300. The lower passivation layer 350 may be formed of or include an insulating material, for example, a resin, but is not limited thereto.

At least portions of the lower line patterns 322 may be exposed through openings of the lower passivation layer 350, and lower pads 330 may be disposed on the exposed lower line patterns 322. External connection terminals 340 may be electrically connected to the lower pads 330, respectively.

The external connection terminals 340 may connect the semiconductor package 1 to a main board of a separate electronic device on which the semiconductor package 1 is mounted. The external connection terminals 340 may be formed of or include at least one of conductive materials such as solder, tin (Sn), silver (Ag), copper (Cu), and aluminum (Al). A shape of the external connection terminal 340 may be changed in various forms such as a land, a bump, a pillar, or a pin in addition to a ball shape.

The encapsulation material 130 may prevent the semiconductor chip 200 from physical and/or chemical damage from the outside by sealing the semiconductor chip 200. The encapsulation material 130 may fill a space in the through hole CA of the core layer 100 and extend on the upper surface of the core layer 100. In other words, the encapsulation material 130 may fill a space between the inner wall of the through hole CA and the semiconductor chip 200 and cover a portion of the upper surface of the semiconductor chip 200 and an upper surface of the core layer 100. In some embodiments, the encapsulation material 130 may fill at least a partial space between the semiconductor chip 200 and the upper package substrate 400. The encapsulation material 130 may be formed of or include an insulating material such as an epoxy resin or a polyimide. However, the material of the encapsulation material 130 is not limited to the above-described materials.

The upper package substrate 400 may include a first upper redistribution layer RDL1 and a second upper redistribution layer RDL2. The upper package substrate 400 may be disposed on an upper surface of the encapsulation material 130 and may be electrically connected to the semiconductor chip 200 and the lower package substrate 300 through the core wiring layers 121 and the core vias 122 of the core layer 100.

The first upper redistribution layer RDL1 may include a first upper insulating layer 411A disposed on the encapsulation material 130, and a first redistribution pattern 420. The first redistribution pattern 420 may include first upper via patterns 421 (e.g., first upper vias), first upper line patterns 422 (e.g., first upper lines), and a first fine pattern FP1. A first seed layer SD1A used as a base of formation of the first redistribution pattern 420 may be provided on a lower surface of the first redistribution pattern 420. Unless otherwise specified, the term “pattern” may refer to a via and/or a line that forms a part of a redistribution layer or other layer. The term “pattern” may also refer to a group of patterns. For example, the term “pattern” may refer collectively to one or more via patterns and one or more line patterns.

The first upper via patterns 421 may each pass through the first upper insulating layer 411A. The first upper via patterns 421 may each be electrically connected to the uppermost core wiring layer 121 of the core layer 100 through a portion of the encapsulation material 130. The first upper line patterns 422 may be disposed on the first upper insulating layer 411A and the first upper via patterns 421. Redistribution of electrical input and output in the first upper redistribution layer RDL1 may be achieved through the first fine pattern FP1.

Among all side surfaces of the first upper via patterns 421, portions of side surfaces of the first upper via patterns 421 may be in contact with the first upper insulating layer 411A, and at least other portions of the side surfaces of the first upper via patterns 421, which are not in contact with the first upper insulating layer 411A, may be in contact with the encapsulation material 130.

The first seed layer SD1A may be disposed between the first upper via patterns 421 and the first upper insulating layer 411A, and between the first upper line patterns 422 and the first upper insulating layer 411A. In the specification, the first upper via patterns 421 and the first upper line patterns 422 are considered as including up to the first seed layer SD1A of the contact lower surface. That is, portions of the side surfaces of the first upper via patterns 421 are shown to be in contact with the first seed layer SD1A and a portion of a side surface of the first seed layer SD1A is shown to be in contact with the first upper insulating layer 411A, but the first seed layer SD1A in contact with the first upper via patterns 421 is included in (e.g., is a part of) the first upper via patterns 421, and thus portions of the side surfaces of the first upper via patterns 421 may be described as being in contact with the first upper insulating layer 411A. At the same time, among all the side surfaces of the first upper via patterns 421, at least other portions of the surfaces of the first upper via patterns 421, which are not in contact with the first upper insulating layer 411A, may be described as being in contact with the encapsulation material 130.

The first upper via patterns 421 may have a tapered shape, a horizontal width of which increases away from the lower package substrate 300.

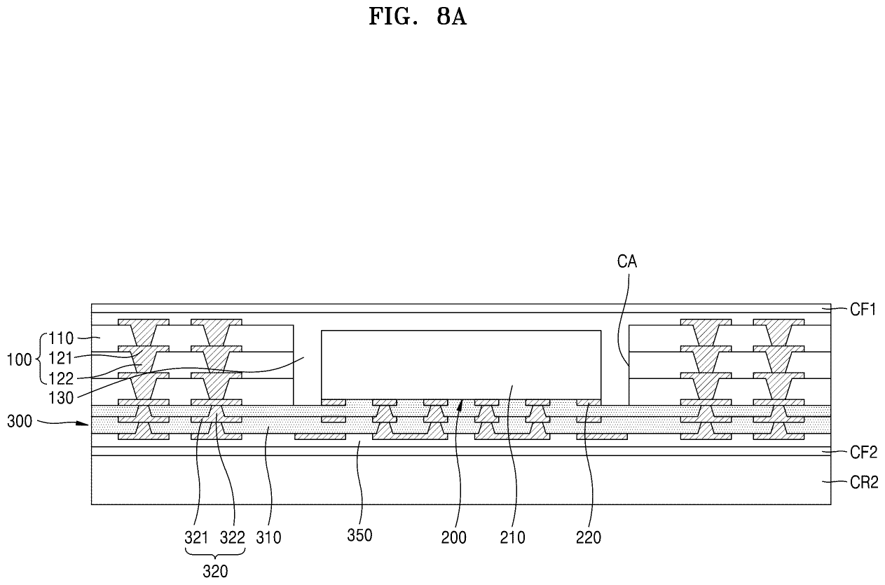

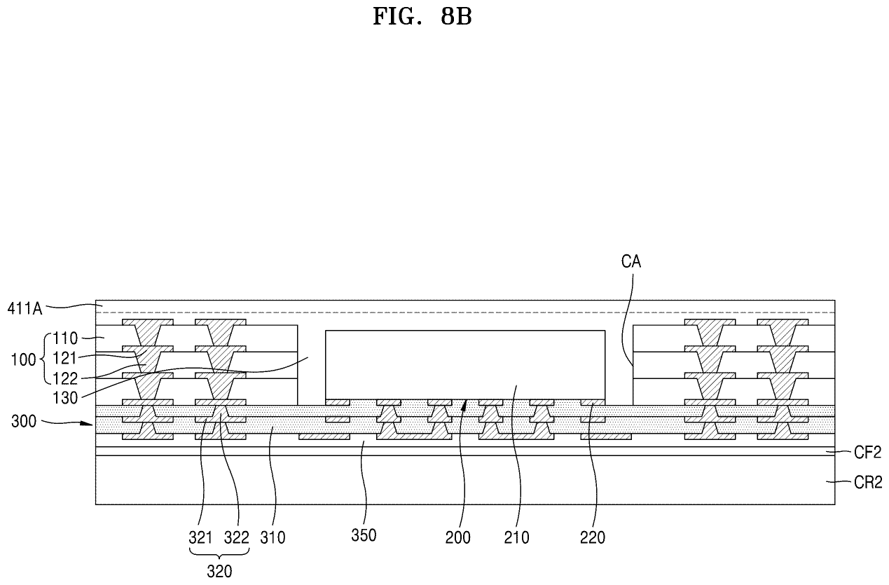

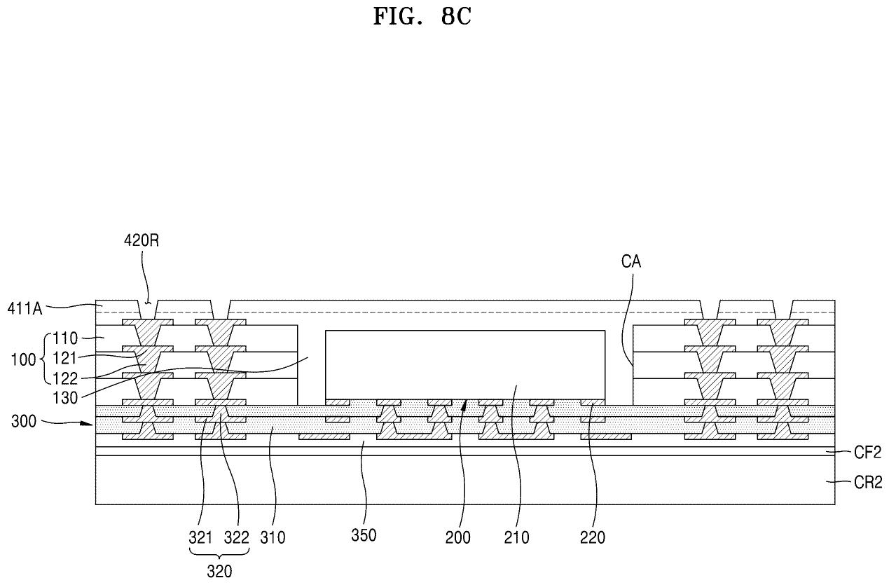

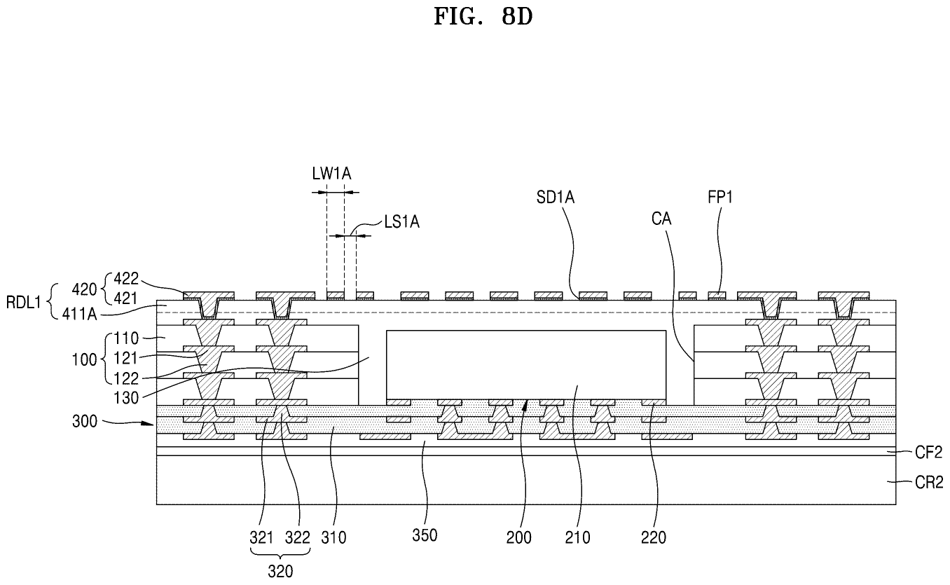

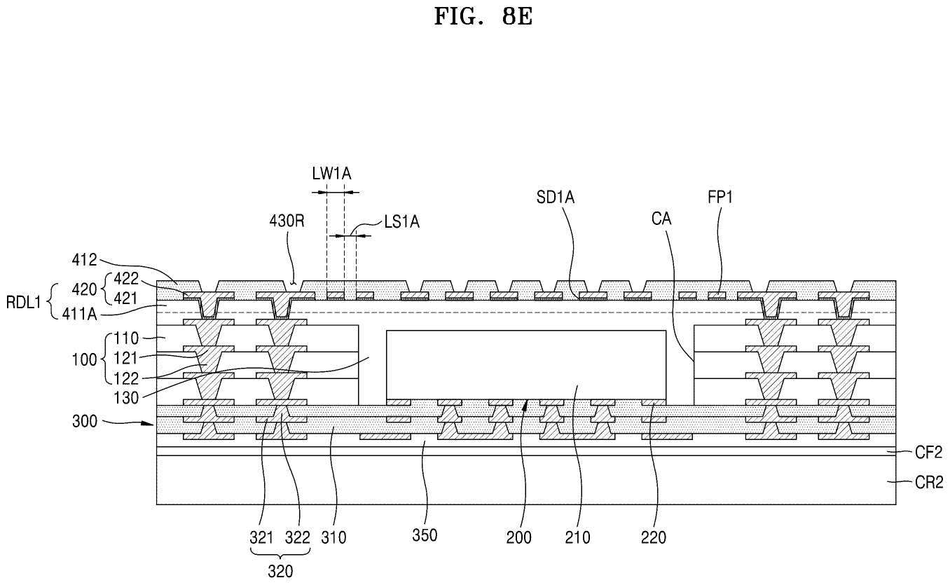

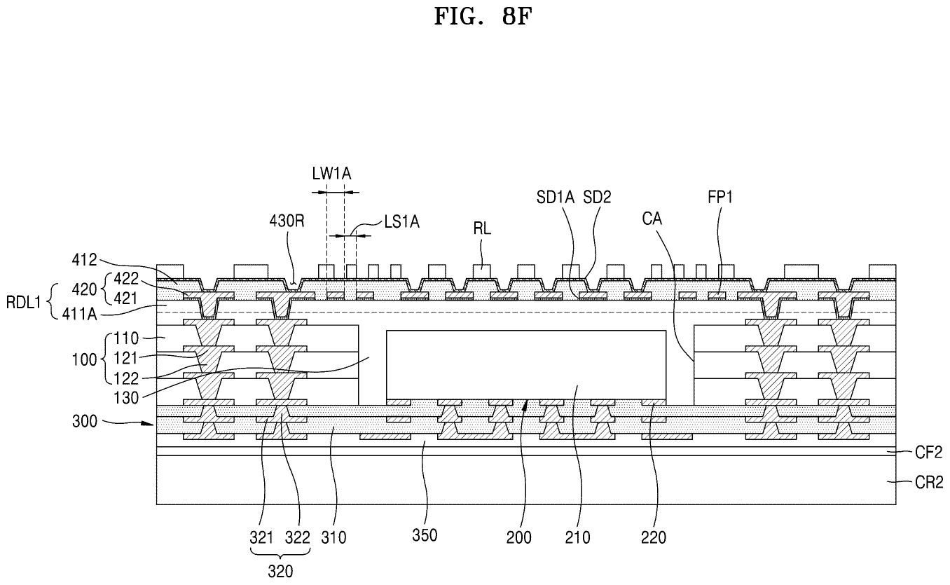

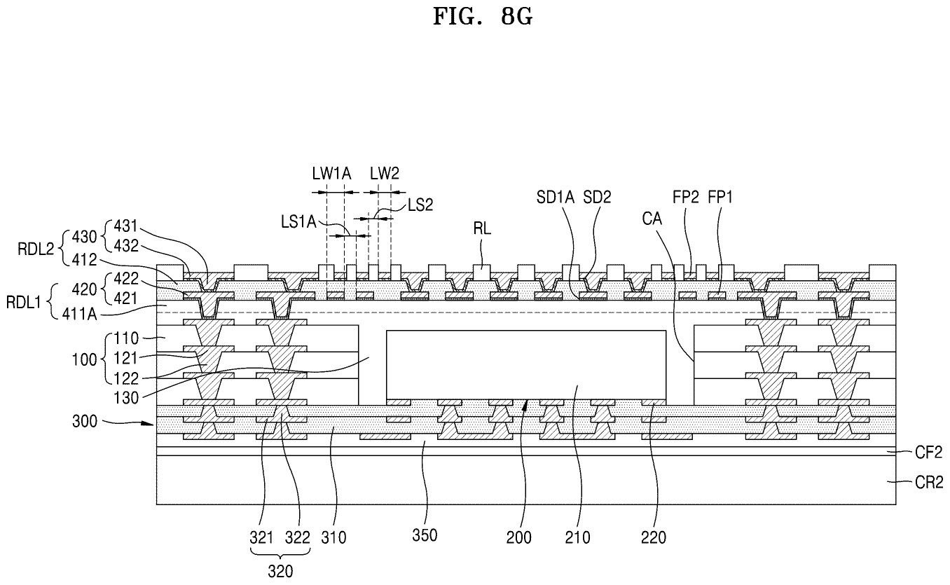

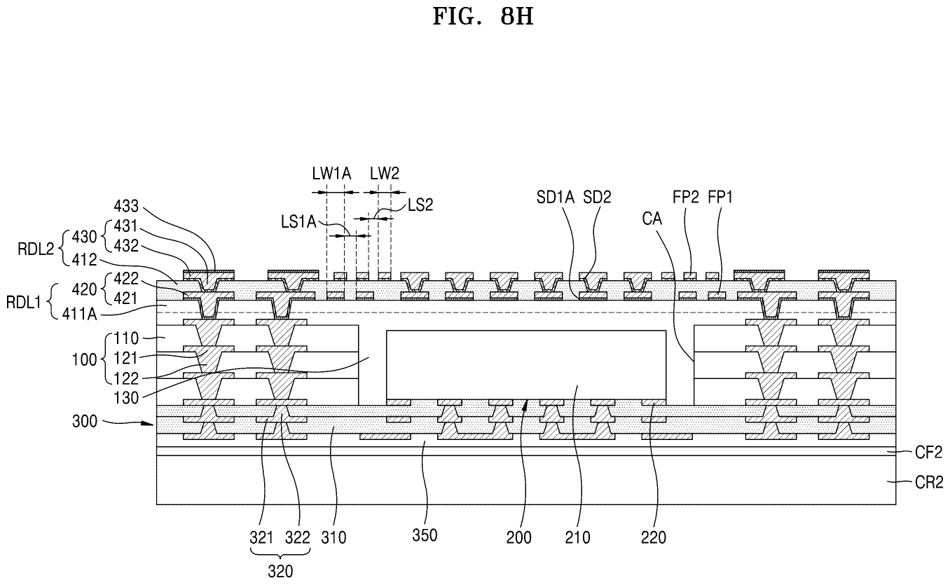

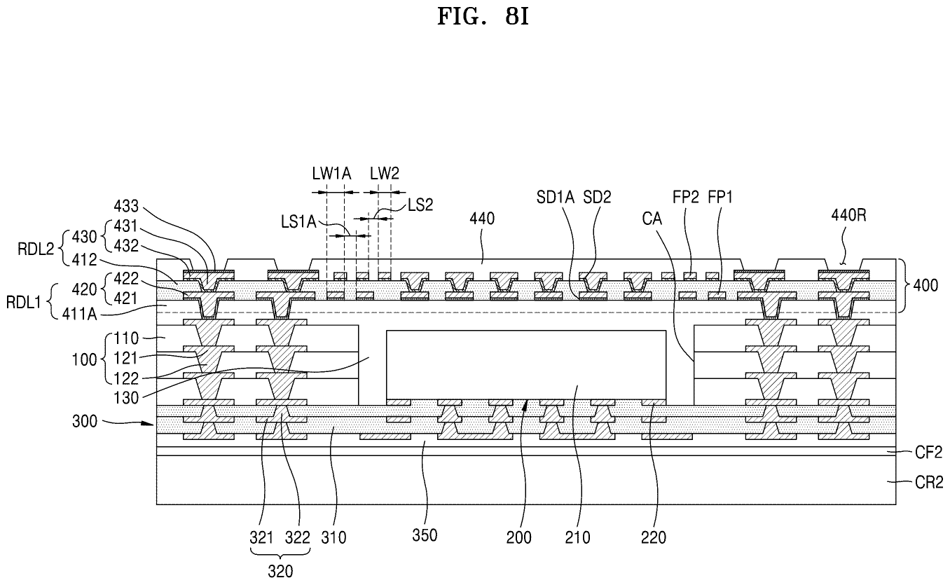

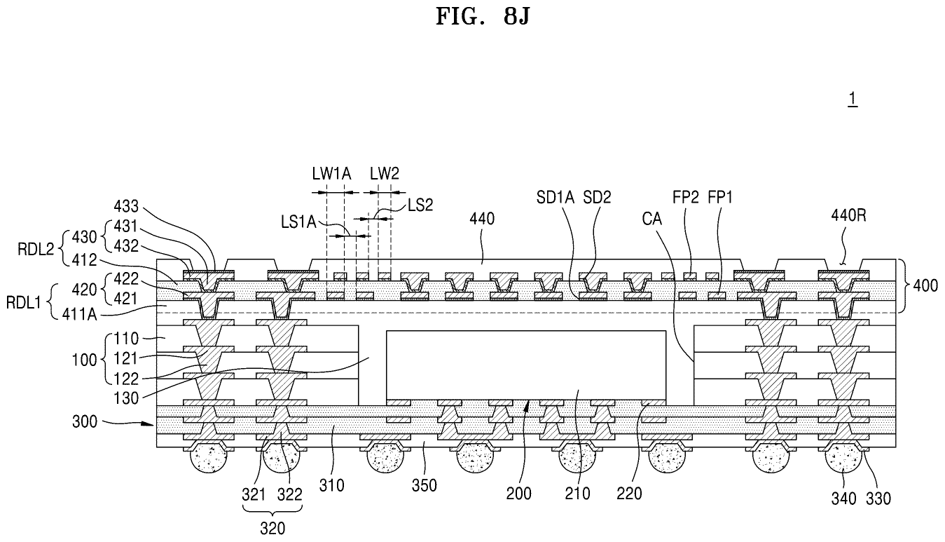

The first upper insulating layer 411A may be processed and a first via hole 420R (refer to FIG. 8C) in which the first redistribution pattern 420 is to be provided may be formed in the first upper insulating layer 411A. For example, the first upper insulating layer 411A may be laser-processed and the first via hole 420R (refer to FIG. 8C) in which the first redistribution pattern 420 is to be provided may be formed in the first upper insulating layer 411A.

The first upper insulating layer 411A may be formed of or include a build up material. According to an embodiment, a build up film as a build up material may be a three-layer structure obtained by combining a resin structure to which a filling material of SiO₂ using an epoxy resin as a main component and a flame retardant are added, with a PET film as a base of the bottom. The build up material may include an Ajinomoto build-up film (ABF) or other laminates. For example, an ABF may be used as the build up material included in the first upper insulating layer 411A. Therefore, according to an embodiment, the encapsulation material 130 and the first upper insulating layer 411A may include the same build up material.

To form the first seed layer SD1A as a base of the first redistribution pattern 420 through electroless plating after the encapsulation material 130 is formed to include an ABF, the first upper insulating layer 411A including an ABF may be newly formed on the upper surface of the encapsulation material 130 including an already hardened ABF. When the first upper insulating layer 411A that is not hardened, which includes an ABF, is formed on the encapsulation material 130 including a hardened ABF, a non-hardened ABF may have greater adhesion with a plating layer in electroless plating than a hardened ABF. Accordingly, to easily form electroless plating for forming the first seed layer SD1A, the first upper insulating layer 411A may be formed by applying the ABF to form the first upper insulating layer 411A on the encapsulation material 130. As such, the reliability of wiring of the semiconductor package 1 according to an embodiment may be improved.

The first seed layer SD1A formed through the electroless plating may be formed of or include one or more materials selected from the group consisting of copper (Cu), nickel (Ni), palladium (Pd), silver (Ag), chromium (Cr), titanium (Ti), and gold (Au).

The second upper redistribution layer RDL2 may include a second upper insulating layer 412 disposed on the first upper insulating layer 411A, and a second redistribution pattern 430. The second redistribution pattern 430 may include second upper via patterns 431, second upper line patterns 432, and a second fine pattern FP2. A second seed layer SD2 used as a base of formation of the second redistribution pattern 430 may be provided on a lower surface of the second redistribution pattern 430. Redistribution of electrical input and output in the second upper redistribution layer RDL2 may be achieved through the second fine pattern FP2. Unlike the diagrams, the semiconductor package 1 according to an embodiment may include three or more redistribution layers by stacking a plurality of second upper redistribution layers RDL2. In this case, the second upper via patterns 431 may be stack vias or staggered vias and may be provided on the preceding second upper redistribution layer RDL2. The stack via refers to a structure in which via patterns are stacked to overlap up and down, and the staggered via refers to a structure in which via patterns are stacked up and down and are laterally arranged at a certain distance offset from each other.

The second upper insulating layer 412 may be provided on the first upper insulating layer 411A and the first redistribution pattern 420. The second upper insulating layer 412 may be formed of or include an insulating material, such as a PID resin. In this case, the second upper insulating layer 412 may further include an inorganic filler.

The second redistribution pattern 430 including the second upper via patterns 431 and the second upper line patterns 432 may be formed on the second upper insulating layer 412. The second upper via patterns 431 may be electrically connected to at least portions of the first upper line patterns 422 of the first upper redistribution layer RDL1 through the second upper insulating layer 412. The second upper line patterns 432 may be disposed on the second upper insulating layer 412 and may be provided on the second upper via patterns 431. A metal plating layer 433 may be provided on at least portions of the second upper line patterns 432. The metal plating layer 433 may be formed of or include a metal including gold (Au) for example.

An upper passivation layer 440 may be disposed on the upper surface of the second upper insulating layer 412 and may protect the upper package substrate 400. The upper passivation layer 440 may include an insulating material, for example, a build up material, but is not limited thereto. The upper passivation layer 440 may include a third hole 440R obtained by recessing a portion of the upper passivation layer 440, through which at least portions of the second upper via patterns 431 and the metal plating layer 433 are exposed. In a package-on-package type package in which an upper semiconductor device 500 described below is stacked on or attached onto another package, upper connection terminals 540 may be located in the third hole 440R.

According to an embodiment, the second upper insulating layer 412 may include a photo imageable dielectric (PID) resin, and the second seed layer SD2, which is a base of the second redistribution pattern 430, may be formed by a sputter process. The second seed layer SD2 may be formed with a smaller line width than in the case in which the second seed layer SD2 is formed through electroless plating. When the second upper insulating layer 412 includes a PID resin, the second seed layer SD2 is accordingly formed by the sputter process, and therefore, a line width of the second seed layer SD2 may be less than a line width of the first seed layer SD1A that is a base of the first redistribution pattern 420 formed through electroless plating. Thus, the line width of the second fine pattern FP2 of the second redistribution pattern 430 may be equal to or less than the line width of the first fine pattern FP1 of the first redistribution pattern 420. In other words, the line width of the first fine pattern FP1 of the first redistribution pattern 420 may be equal to or greater than the line width of the second fine pattern FP2 of the second redistribution pattern 430.

For example, a first line width LW1A and a first line spacing LS1A of the first fine pattern FP1 are equal to or greater than a second line width LW2 and a second line spacing LS2 of the second fine pattern FP2, respectively. The first line width LW1A of the first fine pattern FP1 may be equal to or less than 10 μm, the first line spacing LS1A may be equal to or less than 13 μm, the second line width LW2 of the second fine pattern FP2 may be equal to or less than 9 μm, and the second line spacing LS2 may be equal to or less than 12 μ. Alternatively, the first line width LW1A may be about 5 μm to about 10 μ, the first line spacing LS1 may be about 5 μm to about 13 μm, the second line width LW2 may be about 3 μm to about 9 μm, and the second line spacing LS2 may be about 3 μm to about 12 μm. Alternatively, the second line width LW2 of the second fine pattern FP2 may be equal to or less than 5 μm, and the second line spacing LS2 may be equal to or less than 5 μm.

The entire first redistribution pattern 420 of the first redistribution layer RDL1 may be included in the first fine pattern FP1, or only a part of the first redistribution pattern 420 may be included in the first fine pattern FP1. Similarly, the entire second redistribution pattern 430 of the second redistribution layer RDL2 may be included in the second fine pattern FP2, or only a part of the second redistribution pattern 430 may be included in the second fine pattern FP2.

The line width of some portions of the first redistribution pattern 420 that are not included in the first fine pattern FP1 may exceed 10 μm, and the line spacing may exceed 13 μm. Similarly, the line width of some portions of the second redistribution pattern 430 that are not included in the second fine pattern FP2 may exceed 10 um, and the line spacing may exceed 13 um. The portions of the first redistribution pattern 420 that are not included in the first fine pattern FP1 and the portions of the second redistribution pattern 430 that are not included in the second fine pattern FP2 may collectively be referred to as coarse patterns. For example, the line width and line spacing of the coarse patterns may each range from 13 μm to 100 μm. The coarse patterns may include power lines and ground lines. The first fine pattern FP1 and the second fine pattern FP2 may include signal lines, power lines, and ground lines.

In the semiconductor package 1, a line width of the second fine pattern FP2 may be less than a line width of the first fine pattern FP1. Therefore, in the semiconductor package 1 according to an embodiment, fine patterns of a second package substrate 400 corresponding to a rear redistribution layer may be further refined, thereby improving the performance of the semiconductor package 1.

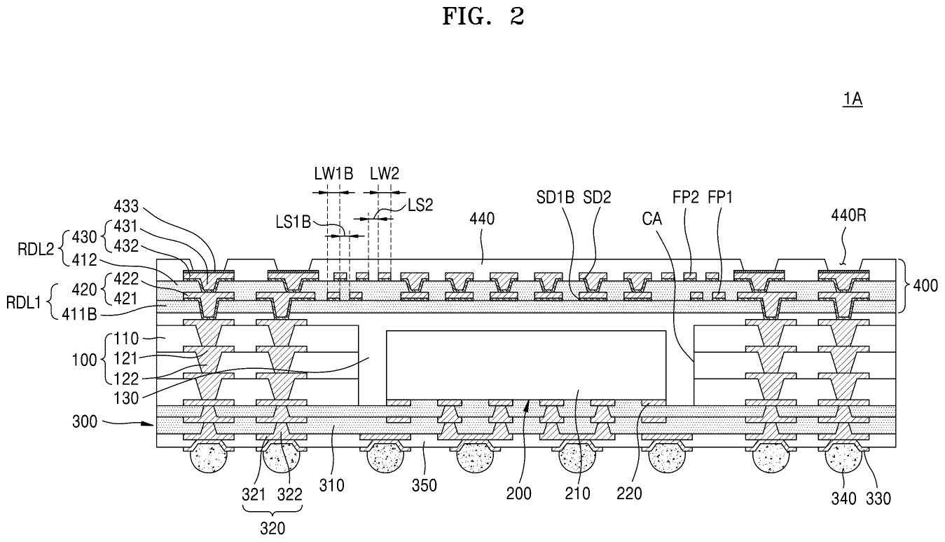

FIG. 2 is a diagram showing a cross section of a semiconductor package 1A according to an embodiment. Descriptions of elements similar to those described above may be omitted.

Referring to FIG. 2, the semiconductor package 1A includes a semiconductor chip 200, a lower package substrate 300 disposed below the semiconductor chip 200, a core layer 100 having a through hole CA to mount the semiconductor chip 200 therein, an encapsulation material 130 surrounding a side surface and upper surface of the semiconductor chip 200 and an upper surface and a partial side surface of the core layer 100, and an upper package substrate 400 disposed on the encapsulation material 130. FIG. 2 is described in terms of a difference from FIG. 1.

The upper package substrate 400 may include a first upper redistribution layer RDL1 and a second upper redistribution layer RDL2.

The first upper redistribution layer RDL1 may include a first upper insulating layer 411B disposed on the encapsulation material 130, and a first redistribution pattern 420. The first redistribution pattern 420 may include first upper via patterns 421, first upper line patterns 422, and a first fine pattern FP1. The first upper via patterns 421 may each pass through the first upper insulating layer 411B. The first upper via patterns 421 may each be electrically connected to the uppermost core wiring layer 121 of the core layer 100 through a portion of the encapsulation material 130. The first upper line patterns 422 may be disposed on the first upper insulating layer 411B and the first upper via patterns 421.

Unlike the semiconductor package 1 according to an embodiment of FIG. 1, in the semiconductor package 1A according to another embodiment of FIG. 2, the first upper insulating layer 411B may include an insulating material that is not a build up material, for example, a photo imageable dielectric (PID) resin. In this case, the first upper insulating layer 411B may further include an inorganic filler.

According to an embodiment, the first upper insulating layer 411B may include a photo imageable dielectric (PID) resin, and a first seed layer SD1B, which is a base of the first redistribution pattern 420, may be formed by a sputter process. The first seed layer SD1B may be formed with a smaller line width than in the case in which the first seed layer SD1B is formed through electroless plating. When the first upper insulating layer 411B includes a PID resin, the first seed layer SD1B is accordingly formed by the sputter process, and therefore, a line width of the first seed layer SD1B formed by the sputter process may be less than a line width of the first seed layer SD1B formed through electroless plating. Thus, a line width of the first micro pattern FP1 of the first redistribution pattern 420 may be further refined.

The range of the first line width LW1B of the first fine pattern FP1 and the range of the second line width LW2 of the second fine pattern FP2 may be the same. The range of the first line spacing LS1B of the first fine pattern FP1 and the range of the second line spacing LS2 of the second fine pattern FP2 may be the same.

For example, the first line width LW1B of the first fine pattern FP1 may be equal to or less than 9 μm, and the first line spacing LS1B may be equal to or less than 12 μm, and similarly, the second line width LW2 of the second fine pattern FP2 may be equal to or less than 9 μm, and the second line spacing LS2 may be equal to or less than 12 μm. Alternatively, the first line width LW1B and the second line width LW2 may each be about 3 μm to about 9 μm, and the first line spacing LS1B and the second line spacing LS2 may each be about 3 μm to about 12 μm. Alternatively, the first line width LW1B and the second line width LW2 of the first fine pattern FP1 may be equal to or less than 5 μm, and the first line spacing LS1B and the second line spacing LS2 of the second fine pattern FP2 may each be equal to or less than 5 μm.

Therefore, in the semiconductor package 1A according to an embodiment, fine patterns of a second package substrate 400 corresponding to a rear redistribution layer may be further refined, thereby improving the performance of the semiconductor package 1A.

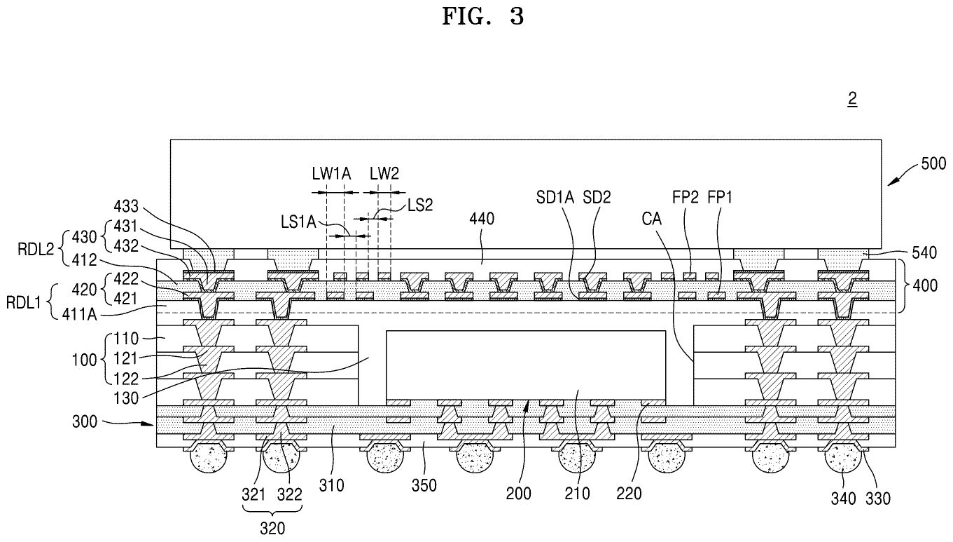

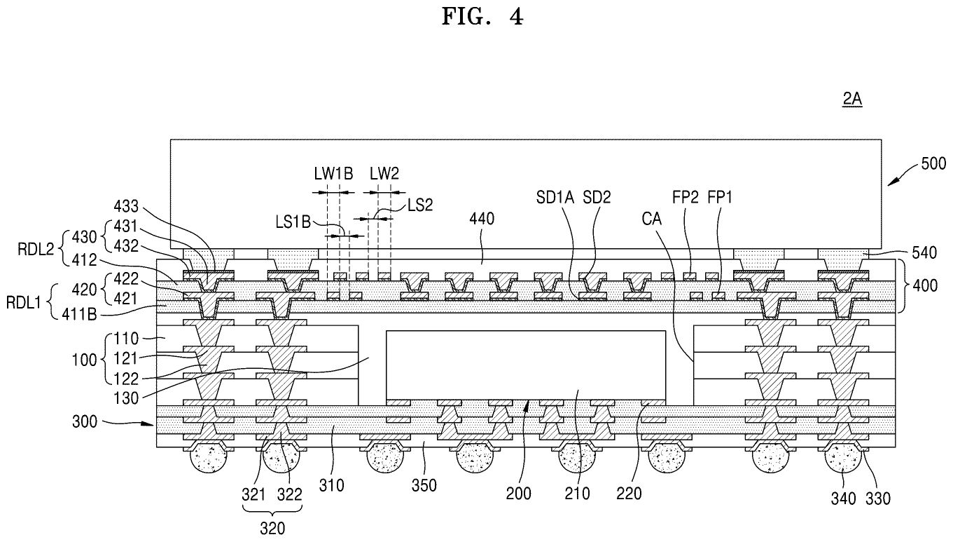

FIG. 3 is a cross-sectional view of a semiconductor package 2 according to an embodiment. FIG. 4 is a cross-sectional view of a semiconductor package 2A according to an embodiment. Descriptions of elements similar to those described above may be omitted.

Referring to FIG. 3, the semiconductor package 2 according to an embodiment may further include an upper semiconductor device 500 mounted on the semiconductor package 1 described with reference to FIG. 1. That is, the semiconductor package 2 may be a package-on-package type package in which the upper semiconductor device 500 corresponding to an upper package is stacked on or attached to the semiconductor package 1 corresponding to a lower package.

The upper semiconductor device 500 may be electrically connected to the upper package substrate 400 through the upper connection terminals 540. The upper connection terminals 540 may be formed of or include at least one of conductive materials such as solder, tin (Sn), silver (Ag), copper (Cu), and aluminum (Al). A shape of the upper connection terminals 540 may be changed in various forms such as a land, a bump, a pillar, or a pin in addition to a ball shape.

The upper semiconductor device 500 may be a semiconductor package including at least one semiconductor chip. At least one of the semiconductor chips included in the upper semiconductor device 500 may include a memory chip, a logic chip, a system on chip (SoC), a power management integrated circuit (PMIC) chip, and a radio frequency integrated circuit (RFIC) chip. The memory chip may include a DRAM chips, a SRAM chip, an MRAM chip, a NAND flash memory chip, and/or a high bandwidth memory (HBM) chip. The logic chip may include an application processor (AP), a micro-processor, a central processing unit (CPU), a controller, and/or an application specific integrated circuit (ASIC). For example, the SoC may include at least two of a logic circuit, a memory circuit, a digital integrated circuit (IC), an RFIC, and an input/output circuit.

Referring to FIG. 4, the semiconductor package 2A according to an embodiment may further include an upper semiconductor device 500 mounted on the semiconductor package 1A described with reference to FIG. 2. That is, the semiconductor package 2A may be a package-on-package type package in which the upper semiconductor device 500 corresponding to an upper package is stacked on or attached to the semiconductor package 1A corresponding to a lower package.

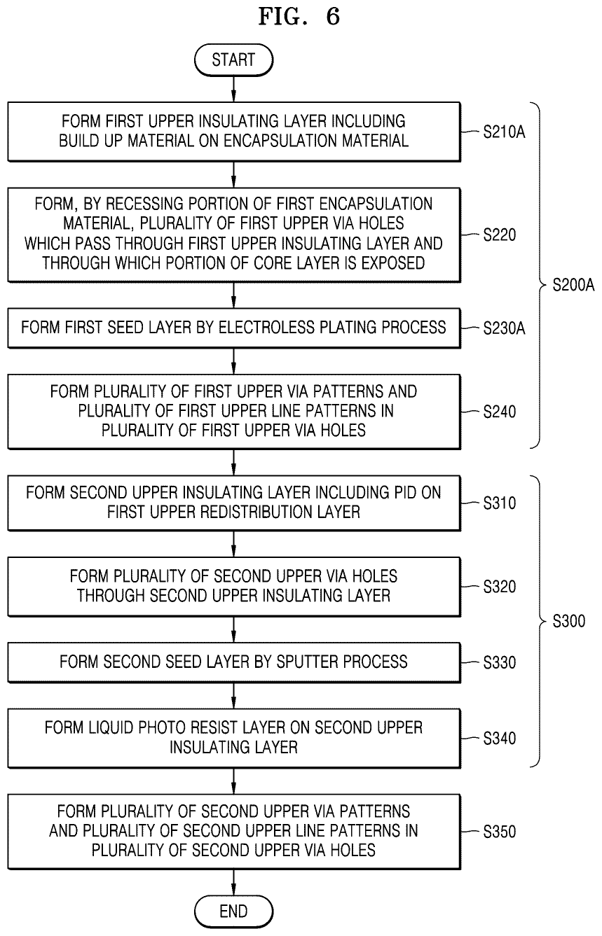

FIG. 5 is a flowchart for explaining a semiconductor package manufacturing method S1 according to an embodiment. FIG. 6 is a flowchart for explaining in more detail the semiconductor package manufacturing method S1 according to an embodiment.

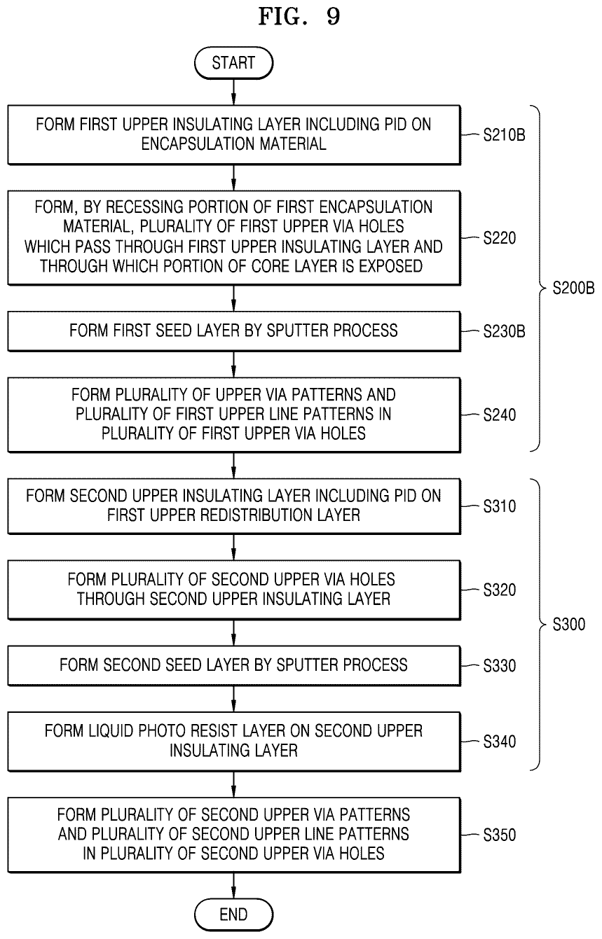

Referring to FIG. 5, the semiconductor package manufacturing method S1 according to an embodiment may include forming a first process structure including a lower package substrate, a first semiconductor device, a core layer, and an encapsulation material (S100), forming a first upper redistribution layer including a first upper insulating layer, a first upper via pattern, and a first upper line pattern (S200A and S200B), and forming a second upper redistribution layer including a second upper line pattern, a second upper via pattern, and a second upper insulating layer (S300). The steps S200A and S200B are shown in more detail in FIGS. 6 and 9, respectively.

FIG. 6 is a flowchart showing in more detail operations S200A of forming the first upper redistribution layer including the first upper insulating layer, the first upper via pattern, and the first upper line pattern and operation S300 of forming the second upper redistribution layer including the second upper line pattern, the second upper via pattern, and the second upper insulating layer.

Referring to FIG. 6, operation S200A of forming the first upper redistribution layer may include forming the first upper insulating layer including a build up material on the encapsulation material (S210A), forming, by recessing a portion of the encapsulation material, a plurality of first upper via holes which pass through the first upper insulating layer and through which a portion of the core layer is exposed (S220), forming a first seed layer using an electroless plating process (S230A), and forming a plurality of first upper via patterns and a plurality of first upper line patterns on the plurality of first upper via holes (S240).

Operation S300 of forming the second upper redistribution layer may include forming the second upper insulating layer including PID on the first upper redistribution layer (S310), forming a plurality of second upper via holes through the second upper insulating layer (S320), forming a second seed layer using a sputter process (S330), forming a liquid photoresist layer on the second upper insulating layer (S340), and forming the plurality of second upper via patterns, and the plurality of second upper line patterns in the plurality of second upper via holes (S350).

The semiconductor package manufacturing method S1 according to an embodiment will be described with reference to FIGS. 5 and 6 with FIGS. 7A to 7F and 8A to 8J described below.

FIGS. 7A to 7F are cross-sectional views for explaining the semiconductor package manufacturing method S1 according to an embodiment. The operation described with reference to FIGS. 7A to 7F may correspond to operation S100 of forming the first process structure including the lower package substrate, the first semiconductor device, the core layer, and the encapsulation material.

Referring to FIG. 7A, the core layer 100 having the through hole CA may be disposed on the tape carrier TC. The core insulating layer 110 may include an insulating material or a resin and may be a multilayer substrate including a plurality of layers, as described above. The core layer 100 may include the core wiring layers 121 disposed between adjacent layers of a plurality of layers of the core insulating layer 110 and disposed on at least a partial surface of upper and lower surfaces of the plurality of layers of the core insulating layer 110.

Referring to FIG. 7B, the semiconductor chip 200 and the connection pads 220 provided on the lower surface of the semiconductor chip 200 may face the tape carrier TC and may be disposed in the through hole CA formed in the core insulating layer 110 such that the active surface of the semiconductor chip 200 faces the tape carrier TC.

Referring to FIG. 7C, the encapsulation material 130 surrounding the semiconductor chip 200 and surrounding a partial side surface and a partial upper surface of the core insulating layer 110 may be formed. The encapsulation material 130 may be formed, and planarization may be separately formed on an upper surface of the encapsulation material 130.

Referring to FIG. 7D, the core wiring layers 121, the core insulating layer 110, and the semiconductor chip 200 disposed on the tape carrier TC may be disposed on a first carrier CR1 such that the upper surface of the semiconductor chip 200 faces the first carrier CR1. A first adhesive layer CF1 for attaching a process product may be disposed between the encapsulation material 130 and the first carrier CR1. The first adhesive layer CF1 may be a copper foil for attachment.

Referring to FIGS. 7E and 7F, the tape carrier TC attached to a side of the lower surface of the semiconductor chip 200, at which the connection pads 220 are located, may be removed, and the lower package substrate 300 may be formed on the surface on which the semiconductor chip 200, the encapsulation material 130, and the core insulating layer 110 are disposed, which is the surface from which the tape carrier TC is removed.

The process of forming the lower package substrate 300 may be achieved by a redistribution process. That is, the lower package substrate 300 may be formed by alternately forming the lower via patterns 321 and the lower line patterns 322 included in the lower insulating layer 310 and the lower redistribution pattern 320. The process result located on the first adhesive layer CF1 on which processes up to the process of FIG. 7F are completed may be referred to as a first process structure herein. That is, the first process structure may include the semiconductor chip 200, the core layer 100, the encapsulation material 130, and the lower package substrate 300.

FIGS. 8A to 8J are cross-sectional views for explaining the semiconductor package manufacturing method S1 according to an embodiment. The operations described with reference to FIGS. 8A to 8J may correspond to operation S200A of forming the first upper redistribution layer including the first upper insulating layer, the first upper via pattern, and the first upper line pattern and operation S300 of forming the second upper redistribution layer including the second upper line pattern, the second upper via pattern, and the second upper insulating layer. In particular, FIGS. 8A to 8D may correspond to operation S200A of forming the first upper redistribution layer and FIGS. 8E to 8J may correspond to operation S300 of forming the second upper redistribution layer.

Referring to FIG. 8A, the first process structure may be removed from the first carrier CR1 with the first adhesive layer CF1 and may be disposed on the second carrier CR2. A second adhesive layer CF2 for attaching the lower package substrate 300 to a second carrier CR2 may be disposed between the lower package substrate 300 and the second carrier CR2. The second adhesive layer CF2 may be a copper foil for attachment, similar to the first adhesive layer CF1.

Referring to FIG. 8B, the first adhesive layer CF1 may be removed from the encapsulation material 130 and the first upper insulating layer 411A may be formed on the encapsulation material 130. According to an embodiment, as described above, the encapsulation material 130 may include a build up material. The first upper insulating layer 411A may also include a build up material. The encapsulation material 130 and the first upper insulating layer 411A may include the same build up material, and for example, the encapsulation material 130 and the first upper insulating layer 411A may be configured including an Ajinomoto build-up film (ABF). FIG. 8B may correspond to operation S210A of forming the first upper insulating layer including a build up material on the encapsulation material.

A certain time elapses after the encapsulation material 130 is formed, and thus the build up material included in the encapsulation material 130 may be hardened. On the other hand, a certain time does not elapse after the first upper insulating layer 411A is formed, and thus the first upper insulating layer 411A may not be completely hardened.

As described below with reference to FIG. 8D, when the first seed layer SD1A is formed via electroless plating, the first seed layer SD1A is formed before the first upper insulating layer 411A is completely hardened, and thus adhesion between the first seed layer SD1A and the first upper insulating layer 411A may be greater than in the case in which the first seed layer SD1A is formed on the encapsulation material 130. That is, the first redistribution pattern 420 based on the first seed layer SD1A may be formed more stably and may also be maintained in a stable state.

Referring to FIG. 8C, the first via hole 420R may be formed in the process product of FIG. 8B. The first via hole 420R may be formed to pass through the first upper insulating layer 411A and through a portion of the encapsulation material 130 to expose a portion of the core layer 100. The first via hole 420R may be formed by laser processing but is not limited thereto. The first via hole 420R may be formed, and Desmear processing may be performed thereon. FIG. 8C may correspond to operation S220 of forming, by recessing a portion of the encapsulation material, the plurality of first upper via holes which pass through the first upper insulating layer and through which a portion of the core layer is exposed.

Due to the characteristics of the process of forming the upper via holes, the first upper via patterns 421 may have a tapered shape, a horizontal width of which increases away from the lower package substrate 300.

Referring to FIG. 8D, electroless plating may be performed to form the first seed layer SD1A. The first seed layer SD1A may be formed in the first via hole 420R and on an upper surface of the first upper insulating layer 411A. The first seed layer SD1A may conformally cover a bottom surface and a sidewall of the first via hole 420R and the upper surface of the first upper insulating layer 411A. The first seed layer SD1A may be formed of or include a conductive material. For example, the first seed layer SD1A may include one or more materials selected from the group consisting of copper (Cu), nickel (Ni), palladium (Pd), silver (Ag), chromium (Cr), titanium (Ti), and gold (Au). Then, a resist pattern having a guide opening may be formed on the first seed layer SD1A. The resist pattern may include a dry film resist (DFR). The guide opening is to form the first redistribution pattern 420.

The first redistribution pattern 420 of FIG. 8D may be formed by performing electroless plating using the first seed layer SD1A as an electrode. As described above, the first redistribution pattern 420 may include first upper via patterns 421, first upper line patterns 422, and a first fine pattern FP1. The first upper via patterns 421, and the first upper line patterns 422 may be formed by a single process.

According to an embodiment, the first redistribution pattern 420 may be formed through a plating process such as an additive process (AP), a semi additive process (SAP), or a modified semi additive process (MSAP). The AP, the SAP, and the MSAP are each an additive process for forming fine patterns, and the three aforementioned additive processes are different from each other in terms of a method of forming a seed layer and a method of removing the seed layer. In the SAP, patterns may be plated using an electroless copper plating layer as a seed layer, and the seed layer may be removed via flash etching after the patterns are plated. The MSAP means to remove a seed layer via quick etching using a copper foil and an electroless copper plating layer as the seed layer. In particular, the first redistribution pattern 420 may be formed by the SAP.

Then, the resist pattern may be removed, for example, by a strip process. Compared to the first redistribution pattern 420, the first seed layer SD1A may be removed by an etching process having etching selectivity for the first seed layer SD1A. FIG. 8D may correspond to operation S230A of forming the first seed layer using an electroless plating process and operation S240 of forming the plurality of first upper via patterns and the plurality of first upper line patterns in the plurality of first upper via holes.

Referring to FIG. 8E, the second upper insulating layer 412 may be formed on a portion of the upper surface of the first upper insulating layer 411A, and a portion of the upper surface of the first redistribution pattern 420. The second upper insulating layer 412 may be formed of or include an insulating material, for example, a PID resin. In this case, the second upper insulating layer 412 may further include an inorganic filler. For example, the second upper insulating layer 412, which includes a PID resin, may be formed to be hardened, and the second via holes 430R may be formed through a photo process.

The sputter process may be performed to form the second seed layer SD2. The second seed layer SD2 may be formed in the second via holes 430R and on an upper surface of the second upper insulating layer 412. The second seed layer SD2 may conformally cover a bottom surface and a sidewall of the second via holes 430R and the upper surface of the second upper insulating layer 412. The second seed layer SD2 may be formed of or include a conductive material. For example, the second seed layer SD2 may include one or more materials selected from the group consisting of copper (Cu), nickel (Ni), palladium (Pd), silver (Ag), chromium (Cr), titanium (Ti), and gold (Au).

FIG. 8E may correspond to operation S320 of forming the plurality of second upper via holes through the second upper insulating layer and operation S330 of forming the second seed layer SD2 using a sputter process.

Referring to FIG. 8F, a resist layer for plating (e.g., a resist layer) RL may be formed on a portion of the upper surface of the second seed layer SD2 formed on the second upper insulating layer 412. For example, the resist layer for plating RL may be a liquid photoresist layer. The resist layer for plating RL may be formed to have guide openings. The guide openings may function as a guide to form the second redistribution pattern 430 later. The guide opening may be located on the second via holes 430R. That is, the guide opening may expose at least a portion of the upper surface of the second seed layer SD2 therethrough.

FIG. 8F may correspond to operation S340 of forming the liquid photoresist layer on the second upper insulating layer.

Referring to FIG. 8G, the second redistribution pattern 430 may be formed through plating on the guide opening of the resist layer for plating RL and the second via holes 430R. The second redistribution pattern 430 may include second upper via patterns 431, second upper line patterns 432, and a second fine pattern FP2. The second upper via patterns 431 may be formed by plating the second via holes 430R, and the second upper line patterns 432 may be formed by filling the guide opening of the resist layer for plating RL. FIG. 8G may correspond to operation S350 of forming the plurality of second upper via patterns and the plurality of second upper line patterns on the plurality of second upper via holes.

As described above, a line width of the second seed layer SD2 may be less than a line width of the first seed layer SD1A.

Thus, the line width of the second fine pattern FP2 of the second redistribution pattern 430 may be equal to or less than the line width of the first fine pattern FP1 of the first redistribution pattern 420. For example, a first line width LW1A and a first line spacing LS1A of the first fine pattern FP1 are equal to or greater than a second line width LW2 and a second line spacing LS2 of the second fine pattern FP2, respectively. The first line width LW1A of the first fine pattern FP1 may be equal to or less than 10 μm, the first line spacing LS1A may be equal to or less than 13 μm, the second line width LW2 of the second fine pattern FP2 may be equal to or less than 9 μm, and the second line spacing LS2 may be equal to or less than 12 μm. Alternatively, the second line width LW2 of the second fine pattern FP2 may be equal to or less than 5 μm, and the second line spacing LS2 may be equal to or less than 5 μm.

Accordingly, in the semiconductor package manufacturing method S1 according to an embodiment, the fine patterns of the second package substrate 400 corresponding to a rear redistribution layer may be refined through materials and processes, thereby improving the semiconductor package manufactured through the semiconductor package manufacturing method S1.

Referring to FIG. 8H, the resist layer for plating RL may be peeled and removed, and the second seed layer SD2 with an upper surface on which the second redistribution pattern 430 is not formed may be removed. Compared to the second redistribution pattern 430, the second seed layer SD2 may be removed by an etching process having etching selectivity for the second seed layer SD2. Referring to FIG. 81, the metal plating layer 433 may be provided on upper surfaces of portions of the second upper line patterns 432. The metal plating layer 433 may be formed of or include a metal including gold (Au) for example. Thereafter, the upper passivation layer 440 may be formed with a third hole 440R on the upper surface of the second upper insulating layer 412. The upper passivation layer 440 may protect the upper package substrate 400. The upper passivation layer 440 may be formed of or include an insulating material, for example, a build up material, but is not limited thereto.

Referring to FIG. 8J, the second carrier CR2 and the second adhesive layer CF2 for attachment of the second carrier CR2 may be removed. At least portions of the lower line patterns 322 may be exposed through openings of the lower passivation layer 350, and lower pads 330 may be disposed on the exposed lower line patterns 322. External connection terminals 340 may be electrically connected to the lower pads 330, respectively. The semiconductor package 1 according to an embodiment may be manufactured through the semiconductor package manufacturing method S1 described above.

FIG. 9 is a flowchart for explaining in more detail the semiconductor package manufacturing method S1 according to an embodiment.

FIG. 9 is a flowchart showing in more detail operation S200B of forming the first upper redistribution layer including the first upper insulating layer, the first upper via pattern, and the first upper line pattern and operation S300 of forming the second upper redistribution layer including the second upper line pattern, the second upper via pattern, and the second upper insulating layer.

Referring to FIG. 9, operation S200B of forming the first upper redistribution layer may include forming the first upper insulating layer including PID on the encapsulation material (S210B), forming, by recessing a portion of a first encapsulation material, a plurality of first upper via holes which pass through the first upper insulating layer and through which a portion of the core layer is exposed (S220), forming a first seed layer using a sputter process (S230B), and forming a plurality of first upper via patterns and a plurality of first upper line patterns on the plurality of first upper via holes (S240).

Operation S300 of forming the second upper redistribution layer may include forming the second upper insulating layer including PID on the first upper redistribution layer (S310), forming a plurality of second upper via holes through the second upper insulating layer (S320), forming a second seed layer using a sputter process (S330), forming a liquid photoresist layer on the second upper insulating layer (S340), and forming the plurality of second upper via patterns, and the plurality of second upper line patterns in the plurality of second upper via holes (S350).

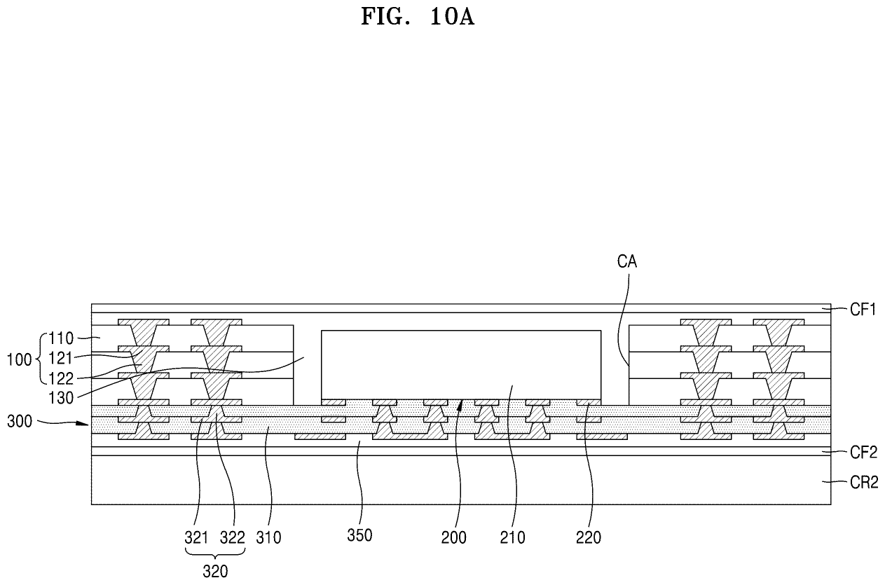

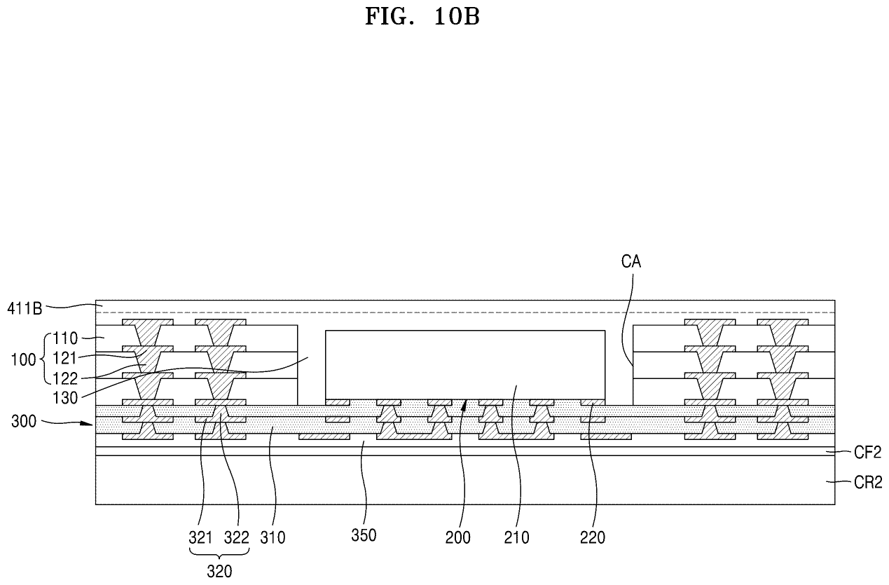

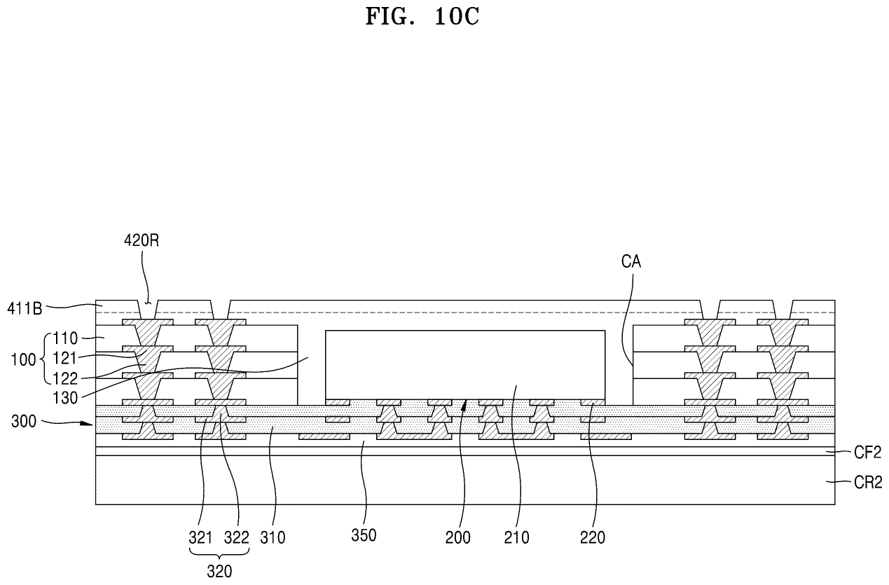

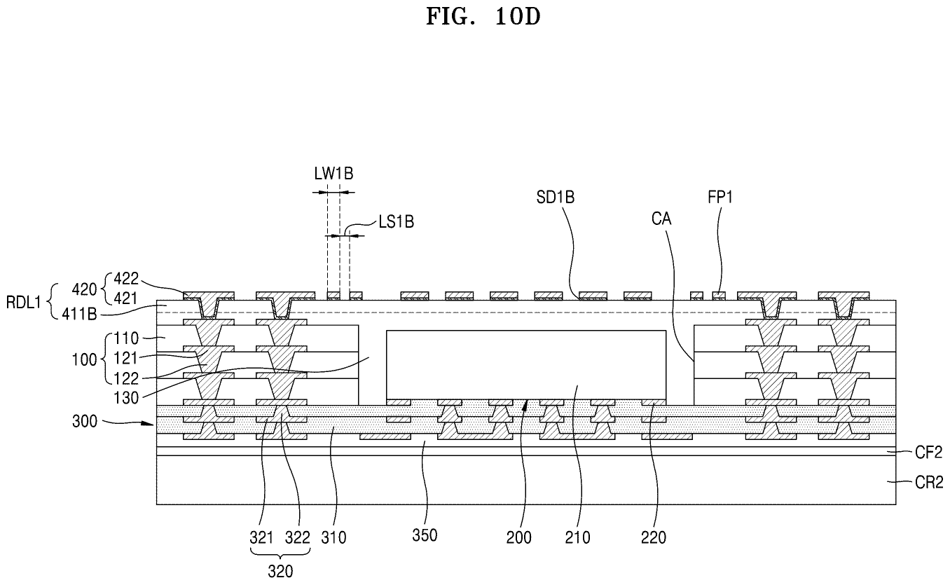

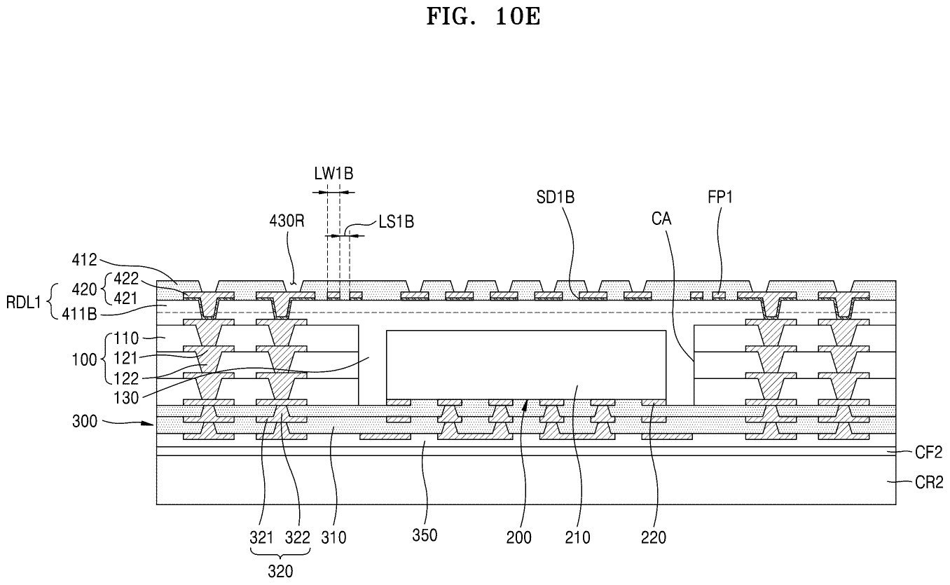

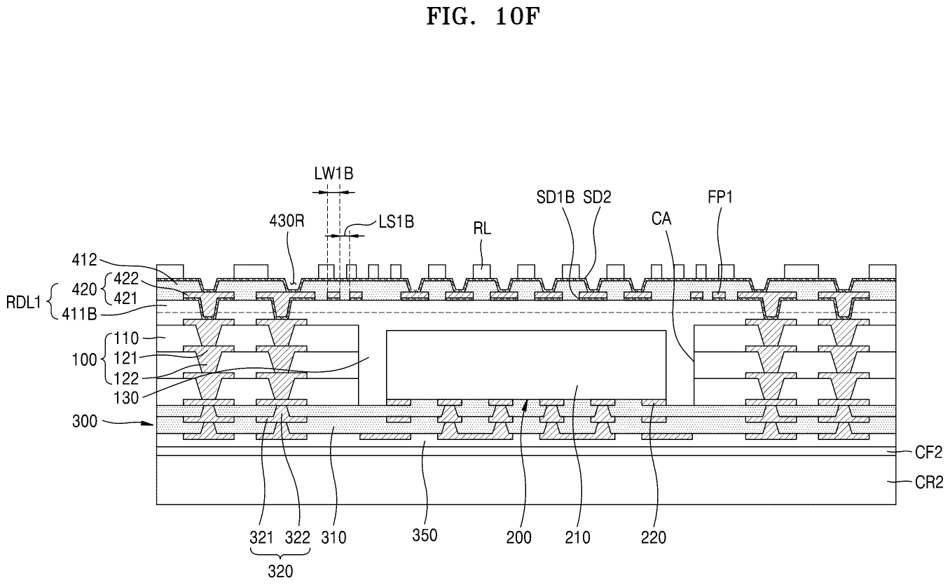

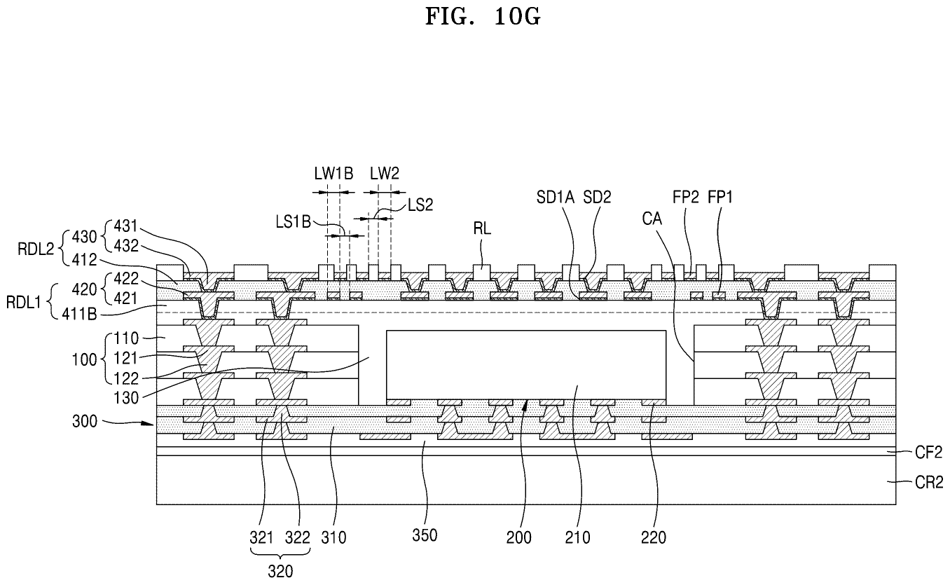

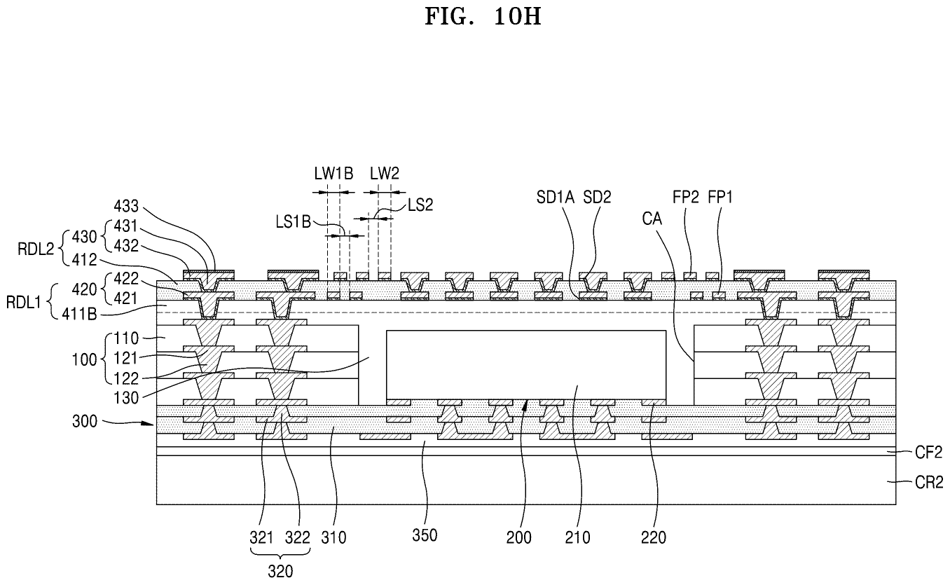

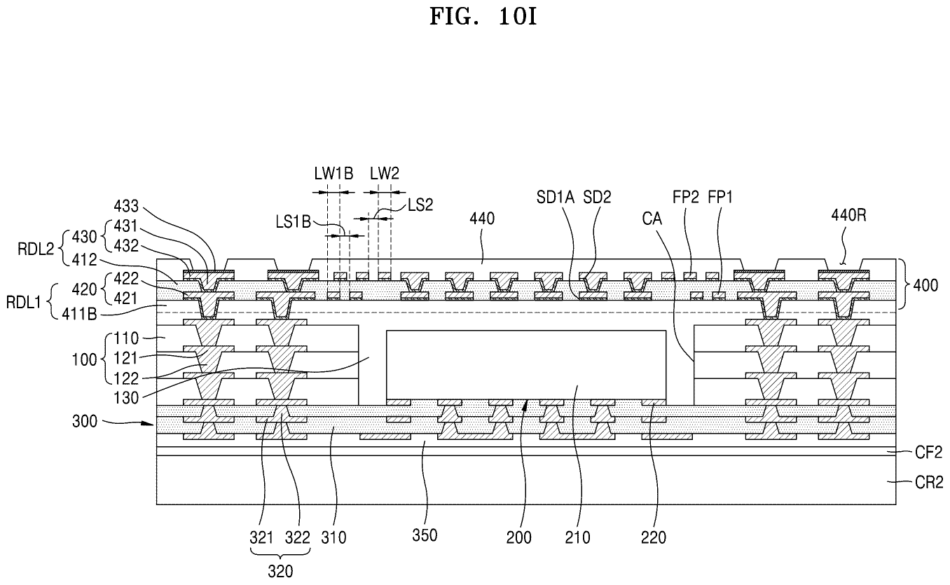

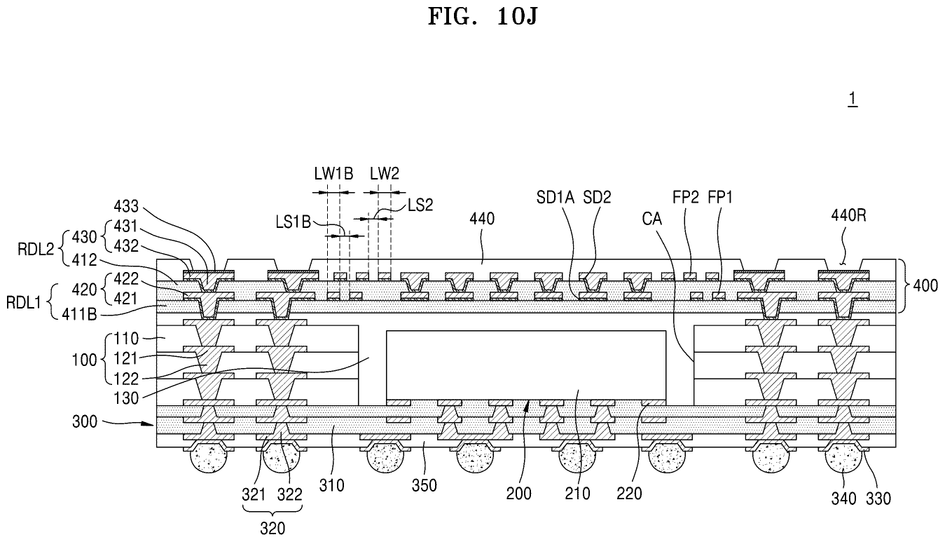

The semiconductor package manufacturing method S1 according to an embodiment will be described with reference to FIG. 9 and FIGS. 10A to 10J.

FIGS. 10A to 10J are cross-sectional views for explaining the semiconductor package manufacturing method S1 according to an embodiment. The operations described with reference to FIGS. 10A to 10J may correspond to operation S200B of forming the first upper redistribution layer including the first upper insulating layer, the first upper via pattern, and the first upper line pattern and operation S300 of forming the second upper redistribution layer including the second upper line pattern, the second upper via pattern, and the second upper insulating layer.

In particular, FIGS. 10A to 10D may correspond to operation S200B of forming the first upper redistribution layer and FIGS. 10E to 10J may correspond to operation S300 of forming the second upper redistribution layer.

Referring to FIG. 10A, the first process structure may be removed from the first carrier CR1 with the first adhesive layer CF1 and may be disposed on the second carrier CR2. The second adhesive layer CF2 may be disposed between the lower package substrate 300 and the second carrier CR2.

Referring to FIG. 10B, the first adhesive layer CF1 may be removed from the encapsulation material 130 and the first upper insulating layer 411B may be formed on the encapsulation material 130. Unlike FIG. 8B, the first upper insulating layer 411B may be formed of or include an insulating material, for example, a PID resin. In this case, the first upper insulating layer 411B may further include an inorganic filler. FIG. 10B may correspond to operation S210B of forming the first upper insulating layer including a PID on the encapsulation material 130.

Referring to FIG. 10C, the first via hole 420R may be formed in the process product of FIG. 10B. The first via hole 420R may be formed to pass through the first upper insulating layer 411B and through a portion of the encapsulation material 130 to expose a portion of the core layer 100. For example, the first upper insulating layer 411B, which includes a PID resin, may be formed to be hardened, and the second via holes 430R may be formed through a photo process. FIG. 10C may correspond to operation S220 of forming, by recessing a portion of the first encapsulation material, the plurality of first upper via holes which pass through the first upper insulating layer and through which a portion of the core layer is exposed.

Due to the characteristics of the process of forming the upper via holes, the first upper via patterns 421 may have a tapered shape, a horizontal width of which increases away from the lower package substrate 300.

Referring to FIG. 10D, a sputtering process may be performed to form the first seed layer SD1B. The first seed layer SD1B may be formed in the first via hole 420R and on an upper surface of the first upper insulating layer 411B. The first seed layer SD1B may conformally cover a bottom surface and a sidewall of the first via hole 420R and the upper surface of the first upper insulating layer 411B. The first seed layer SD1B may be formed of or include a conductive material. For example, the first seed layer SD1B may include one or more materials selected from the group consisting of copper (Cu), nickel (Ni), palladium (Pd), silver (Ag), chromium (Cr), titanium (Ti), and gold (Au).

The first redistribution pattern 420 may be formed on the first seed layer SD1B. According to an embodiment, the first redistribution pattern 420 may be formed through a plating process such as an additive process (AP), a semi additive process (SAP), or a modified semi additive process (MSAP). In particular, the first redistribution pattern 420 may be formed by the SAP.

A line width of the first seed layer SD1B formed by a sputtering process may be less than a line width of the first seed layer formed through electroless plating. Thus, a line width of the first micro pattern FP1 of the first redistribution pattern 420 may be further refined.

For example, the first line width LW1B of the first fine pattern FP1 may be equal to or less than 9 μm, and the first line spacing LS1B may be equal to or less than 12 μm, and similarly, the second line width LW2 of the second fine pattern FP2 may be equal to or less than 9 μm, and the second line spacing LS2 may be equal to or less than 12 μm. Alternatively, the first line width LW1B and the second line width LW2 of the first fine pattern FP1 may be equal to or less than 5 μ, and the first line spacing LS1B and the second line spacing LS2 may be equal to or less than 5 μm.

Accordingly, in the semiconductor package manufacturing method S1 according to an embodiment, a circuit of the second package substrate 400 corresponding to a rear redistribution layer may be refined, thereby improving the performance of the semiconductor package manufactured through the semiconductor package manufacturing method S1.

FIG. 10D may correspond to operation S230B of forming the first seed layer using a sputter process and operation S240 of forming the plurality of first upper via patterns and the plurality of first upper line patterns in the plurality of first upper via holes.

FIGS. 10E to 10J are substantially the same as the operations of FIGS. 8E to 8J, and thus a separate description is omitted.

The semiconductor package 1A according to an embodiment may be manufactured through the semiconductor package manufacturing method S1 described above.

It will be appreciated by those skilled in the art to which the inventive concept belongs that the inventive concept described above may be practiced in other specific forms without altering its technical ideas or essential features. It should therefore be understood that the embodiments described above are examples and non-limiting in all respects.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

While the inventive concept has been particularly shown and described with reference to embodiments thereof, it will be understood that various changes in form and details may be made therein without departing from the spirit and scope of the disclosure.

1. A semiconductor package comprising:
a lower package substrate including lower insulating layers;
a first semiconductor device mounted on the lower package substrate;
a core layer on the lower package substrate, the core layer being laterally spaced apart from the first semiconductor device and including: a core substrate, core vias passing through the core substrate, and core patterns connecting the core vias to each other;
an encapsulation material surrounding the first semiconductor device and covering an upper portion of the core layer; and
an upper package substrate disposed on the encapsulation material, the upper package substrate including a first upper redistribution layer and a second upper redistribution layer,
wherein the first upper redistribution layer includes a first upper insulating layer and a first upper redistribution pattern on the first upper insulating layer,
the second upper redistribution layer includes a second upper insulating layer on the first upper insulating layer and a second upper redistribution pattern on the second upper insulating layer,
a first line width of a first fine pattern of the first upper redistribution pattern is greater than or equal to a corresponding second line width of a second fine pattern of the second upper redistribution pattern, and
a first line spacing of the first fine pattern is greater than or equal to a corresponding second line spacing of the second fine pattern.

2. The semiconductor package of claim 1,
wherein the first upper redistribution pattern includes first upper via patterns and first upper line patterns, the first upper via patterns passing through the first upper insulating layer, and the first upper line patterns being on the first upper insulating layer and electrically connected to the first upper via patterns, and
the first upper via patterns each pass through the first upper insulating layer and the encapsulation material, and
the first upper insulating layer and the encapsulation material are each in contact with at least a portion of a side surface of each of the first upper via patterns.

3. The semiconductor package of claim 2,
wherein the second upper redistribution pattern includes second upper via patterns and second upper line patterns, the second upper via patterns passing through the second upper insulating layer, and the second upper line patterns being on the second upper insulating layer and electrically connected to the second upper via patterns, and
the first upper via patterns and the second upper via patterns each have a tapered shape, a horizontal width of which increases away from the lower package substrate.

4. The semiconductor package of claim 3,
wherein the first upper via patterns and the second upper via patterns each comprise a stack via or a staggered via.

5. The semiconductor package of claim 4,
wherein the first upper insulating layer includes a build up material and the second upper insulating layer includes a photo imageable dielectric (PID).

6. The semiconductor package of claim 5,
wherein the first line width is about 5 μm to about 10 μm and the first line spacing is about 5 μm to about 13 μm, and
the second line width is about 3 μm to about 9 μm and the second line spacing is about 3 μm to about 12 μm.

7. The semiconductor package of claim 6,
wherein the first upper insulating layer and the encapsulation material include an identical material.

8. The semiconductor package of claim 3,
wherein a material of the lower insulating layers and a material of the second upper insulating layer are identical to each other, and
the lower insulating layers and the second upper insulating layer each include a photo imageable dielectric (PID).

9. The semiconductor package of claim 3,
wherein materials of the first upper insulating layer and the encapsulation material are not identical to each other, and the first upper insulating layer and the second upper insulating layer include an identical material.

10. The semiconductor package of claim 9,
wherein the encapsulation material includes a build up material, and
the first upper insulating layer and the second upper insulating layer each include a photo imageable dielectric (PID).

11. The semiconductor package of claim 10,
wherein the first line width and the second line width are each about 3 μm to about 9 μm, and
the first line spacing and the second line spacing are each about 3 μm to about 12 μm.

12. The semiconductor package of claim 3,
further comprising a second semiconductor device mounted on the upper package substrate.

13. The semiconductor package of claim 3,
wherein the semiconductor package further comprises a plurality of the second upper redistribution layers sequentially stacked.

14. A method of manufacturing a semiconductor package, the method comprising:
forming a first process structure including: a lower package substrate, a first semiconductor device mounted on the lower package substrate, a core layer mounted on the lower package substrate, and the core layer being laterally spaced apart from the first semiconductor device, and an encapsulation material surrounding the first semiconductor device on the lower package substrate, the encapsulation material being on the core layer;
forming a first upper redistribution layer, the first upper redistribution layer including: a first upper insulating layer on the encapsulation material of the first process structure and a first upper redistribution pattern on the first upper insulating layer; and
forming a second upper redistribution layer, the second upper redistribution layer including: a second upper insulating layer on the first upper redistribution layer and a second upper redistribution pattern on the second upper insulating layer,
wherein the forming of the first upper redistribution layer includes:
forming the first upper insulating layer on the encapsulation material;
forming, by recessing a portion of the encapsulation material, a plurality of first upper via holes which pass through the first upper insulating layer and through which a portion of the core layer is exposed;
forming a first seed layer on the first upper insulating layer having the plurality of first upper via holes; and
forming first upper via patterns in the plurality of first upper via holes, the first upper via patterns being electrically connected to the core layer, and forming first upper line patterns on the first upper via patterns,
wherein the forming of the second upper redistribution layer includes:
forming a second upper insulating layer on the first upper redistribution layer;
forming a plurality of second upper via holes through the second upper insulating layer;
forming a second seed layer on the second upper insulating layer having the plurality of second upper via holes;
forming a resist layer on the second upper insulating layer on which the second seed layer is formed; and
forming second upper via patterns on the plurality of second upper via holes and forming second upper line patterns on the second upper via patterns,
wherein a material of the first upper insulating layer and a material of the second upper insulating layer are different from each other,
the first upper redistribution pattern and the second upper redistribution pattern are formed such that a first line width of a first fine pattern of the first upper redistribution pattern is greater than or equal to a corresponding second line width of a second fine pattern of the second upper redistribution pattern, the first upper redistribution pattern and the second upper redistribution pattern are formed such that a first line spacing of the first fine pattern is greater than or equal to a corresponding second line spacing of the second fine pattern, and
the first seed layer is formed via electroless plating and the second seed layer is formed using a sputter process.

15. The method of claim 14,
wherein the first upper insulating layer comprises a build up material and the second upper insulating layer comprises a photo imageable dielectric (PID).

16. The method of claim 15,
wherein the first line width of the first fine pattern is about 5 μm to about 10 μm and the first line spacing is about 5 um to about 13 um, and
the second line width of the second fine pattern is about 3 μm to about 9 μm and the second line spacing is about 3 μm to about 12 μm.

17. The method of claim 16,
wherein the first upper redistribution pattern is formed using a semi additive process (SAP), and
the resist layer comprises a liquid photo resist (LPR).

18. The method of claim 15, wherein the encapsulation material comprises a second build up material,
wherein the forming of the first upper redistribution layer includes:
allowing the encapsulation material to harden before forming the first upper insulating layer, and
forming the first seed layer on the first upper insulating layer before the first upper insulating layer hardens.

19. A method of manufacturing a semiconductor package, the method comprising:
forming a first process structure including: a lower package substrate, a first semiconductor device mounted on the lower package substrate, a core layer mounted on the lower package substrate, the core layer being laterally spaced apart from the first semiconductor device, and an encapsulation material surrounding the first semiconductor device on the lower package substrate, the encapsulation material being on the core layer;
forming a first upper redistribution layer, the first upper redistribution layer including: a first upper insulating layer on the encapsulation material of the first process structure and a first upper redistribution pattern on the first upper insulating layer; and
forming a second upper redistribution layer, the second upper redistribution layer including: a second upper insulating layer on the first upper redistribution layer and a second upper redistribution pattern on the second upper insulating layer,
wherein the forming of the first upper redistribution layer includes:
forming the first upper insulating layer on the encapsulation material;
forming, by recessing a portion of the encapsulation material, a plurality of first upper via holes which pass through the first upper insulating layer and through which a portion of the core layer is exposed;
forming a first seed layer on the first upper insulating layer having the plurality of first upper via holes; and
forming first upper via patterns in the plurality of first upper via holes, the first upper via patterns being electrically connected to the core layer, and forming first upper line patterns on the first upper via patterns,
the forming of the second upper redistribution layer includes:
forming a second upper insulating layer on the first upper redistribution layer;
forming a plurality of second upper via holes through the second upper insulating layer;
forming a second seed layer on the second upper insulating layer having the plurality of second upper via holes;
forming a resist layer on the second upper insulating layer on which the second seed layer is formed; and
forming second upper via patterns on the plurality of second upper via holes and forming second upper line patterns on the second upper via patterns,
wherein a material of the first upper insulating layer and a material of the second upper insulating layer are identical to each other, and
the first seed layer and the second seed layer are each formed using a sputter process.

20. The method of claim 19,
wherein the first upper insulating layer and the second upper insulating layer each comprise a photo imageable dielectric (PID).

21-24. (canceled)
